(19) United States
(12) Patent Application Publication
(10) Pub. No.: US 2026/0089979 A1
(43) Pub. Date: Mar. 26, 2026

(54) SEMICONDUCTOR DEVICE AND ELECTRONIC SYSTEM INCLUDING THE SAME

(71) Applicant: SAMSUNG ELECTRONICS CO., LTD., Suwon-si (KR)

(72) Inventors: Sejie TAKAKI, Suwon-si (KR); Seunghyun Lee, Suwon-si (KR); Kyungdong Kim, Suwon-si (KR); Jeehoon Han, Suwon-si (KR)

(73) Assignee: SAMSUNG ELECTRONICS CO., LTD., Suwon-si (KR)

(21) Appl. No.: 19/094,012

(22) Filed: Mar. 28, 2025

(30) Foreign Application Priority Data
Sep. 25, 2024 (KR) 10-2024-0129857

(51) Int. Cl. H10B 80/00; H01L 23/00; H01L 25/065; H01L 25/18; H10B 41/27; H10B 43/27

(52) U.S. Cl. CPC H10B 80/00; H10B 41/27; H10B 43/27; H10W 90/00; H10W 90/792

(57) ABSTRACT

A semiconductor device according to an embodiment includes a circuit region; and a cell region stacked on the circuit region, wherein the cell region comprises a plurality of memory groups, wherein each of the plurality of memory groups comprises a plurality of memory portions, wherein a first plurality of memory portions in a first memory group from the plurality of memory groups are connected to through a first wiring connection, and wherein the first memory group among the plurality of memory groups is connected to a second memory group among the plurality of memory groups through a second wiring connection different from the first wiring connection.

### CROSS-REFERENCE TO RELATED APPLICATION

This application claims priority to and the benefit of Korean Patent Application No. 10-2024-0129857 filed in the Korean Intellectual Property Office on Sep. 25, 2024, the entire disclosure of which is incorporated herein by reference in its entirety.

### BACKGROUND

The present disclosure relates to a semiconductor device and an electronic system including the same.

In an electronic system implementing a data storage, a semiconductor device capable of storing high-capacity data is in demand. Accordingly, a method for increasing a data storage capacity of a semiconductor device is being researched. For example, as one method for increasing the data storage capacity of a semiconductor device, a semiconductor device including three-dimensionally arranged memory cells instead of two-dimensionally arranged memory cells has been proposed.

### SUMMARY

The present disclosure attempts to provide a semiconductor device capable of enhancing performance and productivity and an electronic system including the same.

A semiconductor device according to an embodiment includes a circuit region; and a cell region stacked on the circuit region, wherein the cell region comprises a plurality of memory groups, wherein each of the plurality of memory groups comprises a plurality of memory portions, wherein a first plurality of memory portions in a first memory group from the plurality of memory groups are connected to through a first wiring connection, and wherein the first memory group among the plurality of memory groups is connected to a second memory group among the plurality of memory groups through a second wiring connection different from the first wiring connection.

A semiconductor device according to an embodiment includes a circuit region and a cell region stacked on the circuit region. The cell region includes a plurality of memory sets, and each of the plurality of memory sets includes a plurality of memory groups. Each of the plurality of memory groups includes a plurality of memory portions. The a first plurality of memory portions in a first memory group from the plurality of memory groups are connected to through a first wiring connection,, the first memory group among the plurality of memory groups is connected to a second memory group among the plurality of memory groups through a second wiring connection different from the first wiring connection in each of the memory set and the plurality of memory sets are connected to each other through a third wiring connection different from the second wiring connection.

An electronic system according to an embodiment includes a main substrate, a semiconductor device on the main substrate, and a controller connected to the semiconductor device on the main substrate. The semiconductor device according includes a circuit region and a cell region stacked on the circuit region. The cell region includes a plurality of memory groups, and each of the plurality of memory groups includes a plurality of memory portions. The first plurality of memory portions in a first memory group from the plurality of memory groups are connected to through a first wiring connection, and the first memory group among the plurality of memory groups is connected to a second memory group among the plurality of memory groups through a second wiring connection different from the first wiring connection.

### BRIEF DESCRIPTION OF DRAWINGS

FIG. 1 is a cross-sectional view that illustrates a semiconductor device according to an embodiment.

FIG. 2 is a cross-sectional view that illustrates a cell array region of a memory portion included in the semiconductor device illustrated in FIG. 1.

FIG. 3 is an enlarged cross-sectional view that illustrates an example of a channel structure included in the semiconductor device illustrated in FIG. 2.

FIG. 4 illustrates a wiring connection structure of the semiconductor device illustrated in FIG. 1.

FIG. 5 illustrates a wiring connection structure of a semiconductor device according to an embodiment.

FIG. 6 illustrates a wiring connection structure of a semiconductor device according to an embodiment.

FIG. 7 illustrates a wiring connection structure of a semiconductor device according to an embodiment.

FIG. 8 illustrates a wiring connection structure of a semiconductor device according to an embodiment.

FIG. 9 illustrates a wiring connection structure of a semiconductor device according to an embodiment.

FIG. 10 schematically illustrates a wiring connection structure of a semiconductor device according to an embodiment.

FIG. 11 illustrates an electronic system including a semiconductor device according to an embodiment.

FIG. 12 is a perspective view that illustrates an electronic system including a semiconductor device according to an embodiment.

FIG. 13 is a cross-sectional view that illustrates a semiconductor package according to an embodiment.

### DETAILED DESCRIPTION

Embodiments of the present disclosure will be described more fully hereinafter with reference to the accompanying drawings for those skilled in the art to which the present disclosure pertains to easily practice the present disclosure. The present disclosure may be implemented in various different forms and is not limited to the embodiment provided herein.

A portion unrelated to the description is omitted in order to clearly describe the present disclosure, and the same or similar components are denoted by the same reference numeral throughout the present specification.

Further, since a size and/or a thickness of a portion, a region, a member, a unit, a layer, a film, a substrate, or the like illustrated in the accompanying drawings may be arbitrarily illustrated for better understanding and convenience of explanation, the present disclosure is not limited to the illustrated size and/or thickness. In the drawings, a thickness of a portion, a region, a member, a unit, a layer, a film, a substrate, or the like may be enlarged or exaggerated for convenience of explanation and/or simple illustration

It will be understood that when a component such as a portion, a region, a member, a unit, a layer, a film, a substrate, or the like is referred to as being “on” another component, it may be directly on another component or an intervening component may also be present. In contrast, when a component is referred to as being “directly on” another component, there is no intervening component present. Further, when a component is referred to as being “on” or “above” a reference component, a component may be disposed on or below the reference component, and does not necessarily be “on” or “above” the reference component toward an opposite direction of gravity.

In addition, throughout the specification, unless explicitly described to the contrary, the word “comprise”, “include”, or “contain”, and variations such as “comprises”, “comprising”, “includes”, “including”, “contains” or “containing” will be understood to imply the inclusion of other components rather than the exclusion of any other components.

Any blocks or structures shown in the accompanying drawings and described above may be implemented in circuitry such as processing circuitry and/or hardware including logic circuits; a hardware/software combination such as a processor executing software; or a combination thereof. For example, the circuitry more specifically may include, but is not limited to, a central processing unit (CPU), an arithmetic logic unit (ALU), a digital signal processor, a microcomputer, a field programmable gate array (FPGA), a System on chip (SoC), a programmable logic unit, a microprocessor, application-specific integrated circuit (ASIC), etc.

Further, throughout the specification, a phrase “on a plane”, “in a plane”, “on a plan view”, or “in a plan view” may indicate a case where a portion is viewed from above or a top portion, and a phrase “on a cross-section” or “in a cross-sectional view” may indicate a case where a cross-section taken along a vertical direction is viewed from a side.

According to an embodiment, a plurality of memory portions that are included in each of a plurality of memory groups may be electrically connected to have a first wiring connection structure, and the plurality of memory groups may be electrically connected to have a second wiring connection structure different from the first wiring connection structure, thereby enhancing performance and productivity of a semiconductor device together. That is, by an organic connection of a sub-connection (e.g., a primary connection that electrically connects the plurality of memory portions) and a super-connection (e.g., a secondary connection that electrically connects the plurality of memory groups), the performance and the productivity of the semiconductor device may be enhanced in balance.

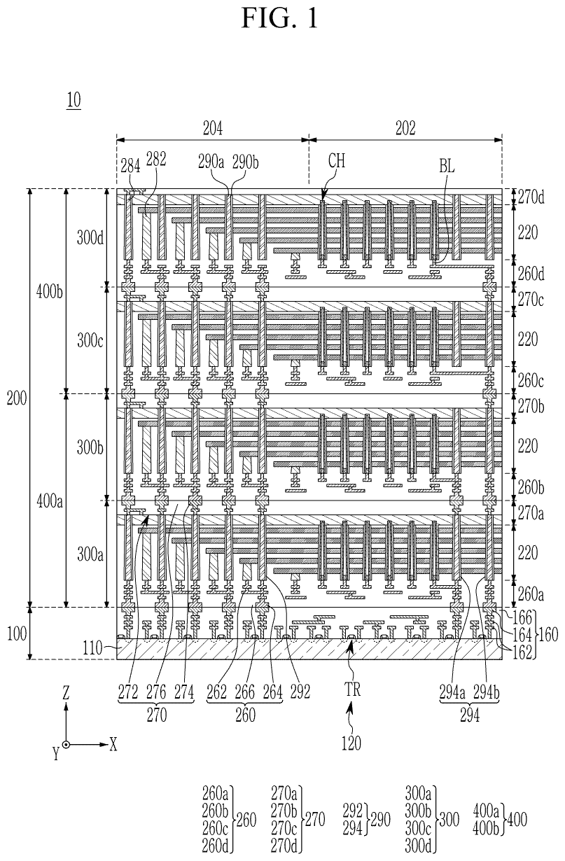

Hereinafter, referring to FIG. 1 to FIG. 4, a semiconductor device according to an embodiment will be described in detail.

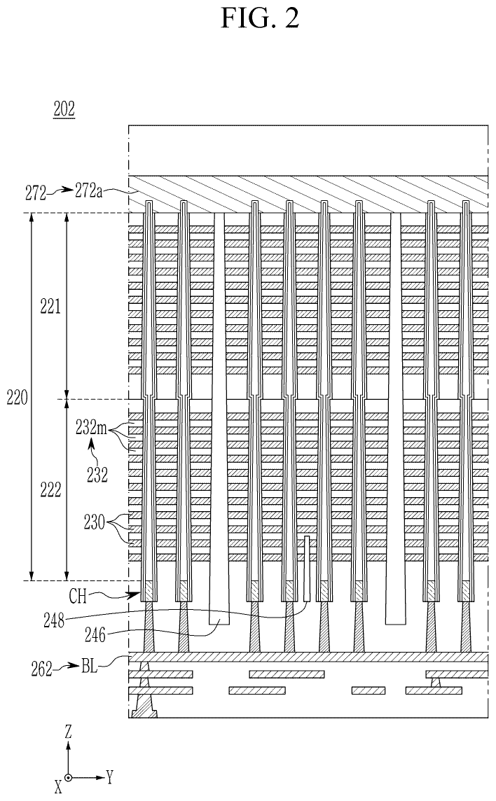

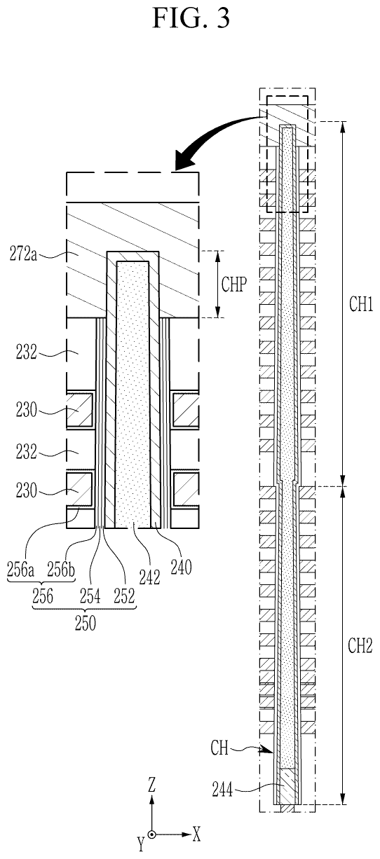

FIG. 1 is a cross-sectional view that schematically illustrates a semiconductor device 10 according to an embodiment. FIG. 2 is a cross-sectional view that illustrates a cell array region 202 of a memory portion 300 included in the semiconductor device 10 illustrated in FIG. 1. FIG. 3 is an enlarged cross-sectional view that illustrates an example of a channel structure CH included in the semiconductor device 10 illustrated in FIG. 2.

FIG. 1 schematically illustrates a gate stacking structure 220 and a channel structure CH, and FIG. 2 and FIG. 3 specifically illustrate the gate stacking structure 220 and the channel structure CH. In FIG. 1, an electrical connection structure of rightmost bit lines BL among a plurality of bit lines BL connected to a plurality of channel structures CH is illustrated. Coordinates of FIG. 1 are based on coordinates of a cell array region 202 where the channel structures CH are disposed. For a clear understanding and simple illustration, in FIG. 1, positions of source contact portions 284 and bit plugs 294 are conceptually illustrated regardless of coordinates.

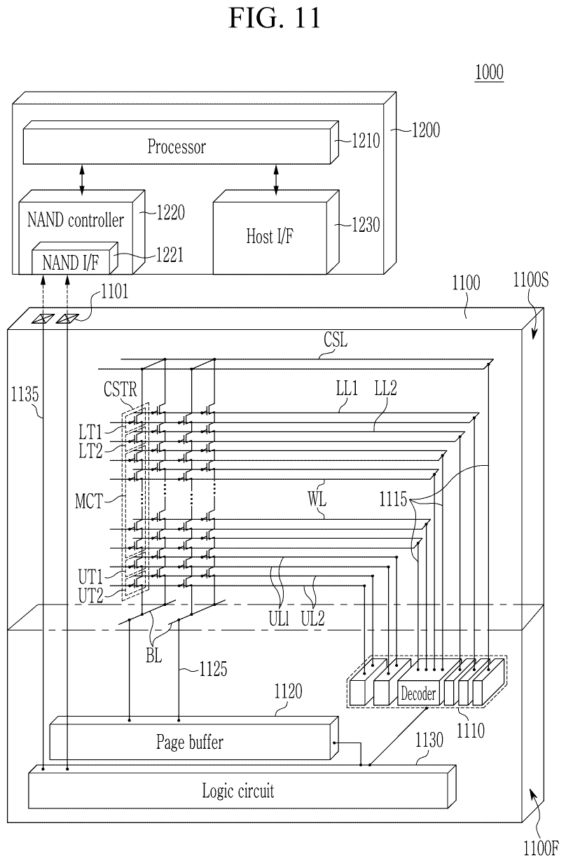

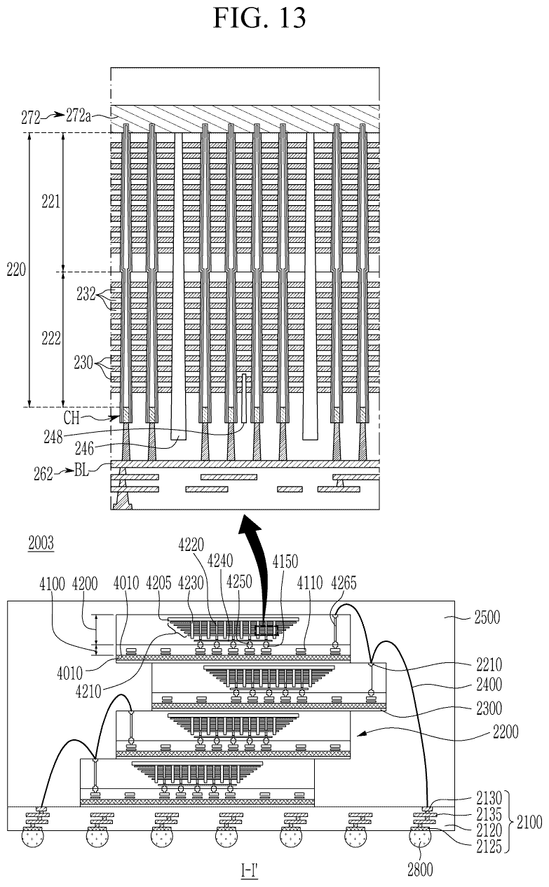

Referring to FIG. 1, a semiconductor device 10 according to an embodiment may include a cell region 200 that includes a memory cell structure and a circuit region 100 that includes a peripheral circuit structure configured to control an operation of the memory cell structure. For example, the circuit region 100 and the cell region 200 may correspond to a first structure 1100F and a second structure 1100S of a semiconductor device 1100 included in an electronic system 1000 illustrated in FIG. 11, respectively. For example, the circuit region 100 and the cell region 200 may be portions including a first structure 4100 and a second structure 4200 of a semiconductor chip 2200 illustrated in FIG. 13, respectively.

In an embodiment, the cell region 200 may be disposed on the circuit region 100. Accordingly, an area corresponding to the circuit region 100 does not need to be secured separately from the cell region 200. Therefore, an area of the semiconductor device 10 may be reduced.

In an embodiment, the semiconductor device 10 may be formed by forming the cell region 200 separately from the circuit region 100 and bonding the cell region 200 to the circuit region 100. For example, the semiconductor device 10 may be a bonding vertical NAND (BV-NAND). The cell region 200 may include a plurality of memory portions 300. The plurality of memory portions 300 may be stacked and bonded to each other in a thickness direction of the semiconductor device 10 (a Z-axis direction in the drawings or a vertical direction) to form the cell region 200. That is, in an embodiment, the semiconductor device 10 may have a multi-bonding structure where the circuit region 100 and the plurality of memory portions 300 are bonded to each other. The memory portion 300 may be referred to as a semiconductor chip or a memory chip.

For example, the circuit region 100 and the memory portion 300 and/or adjacent two memory portions of the plurality of memory portions 300 may be bonded by hybrid bonding that includes metal bonding and insulation layer bonding. For example, the circuit region 100 and the memory portion 300 and/or adjacent two memory portions of the plurality of memory portions 300 may be bonded by a chip to chip (C2C) bonding process, a die-to-wafer bonding, a chip-to-wafer bonding process, or a wafer-to-wafer bonding process. It is understood that the disclosure is not limited thereto.

One circuit region 100 may be shared in the plurality of memory portions 300 that are included in the cell region 200. Thereby, a structure of the semiconductor device 10 may be simplified. The circuit region 100 and the plurality of memory portions 300 are separately formed, and structures and processes suitable for the circuit region 100 and the plurality of memory portions 300 may be applied.

The circuit region 100 may include a substrate 110, and a circuit element 120 and a circuit wiring portion 160 on the substrate 110.

The substrate 110 may be a semiconductor substrate including a semiconductor material. For example, the substrate 110 may be a semiconductor substrate including or being formed of a semiconductor material or may be a semiconductor substrate in which a semiconductor layer is on a base substrate. For example, the substrate 110 may have a single-crystalline, epitaxial, or polycrystalline structure, and/or include or be formed of silicon, germanium, or silicon-germanium. For example, the substrate 110 may include or be formed silicon on insulator (SOI), germanium on insulator (GOI), or the like.

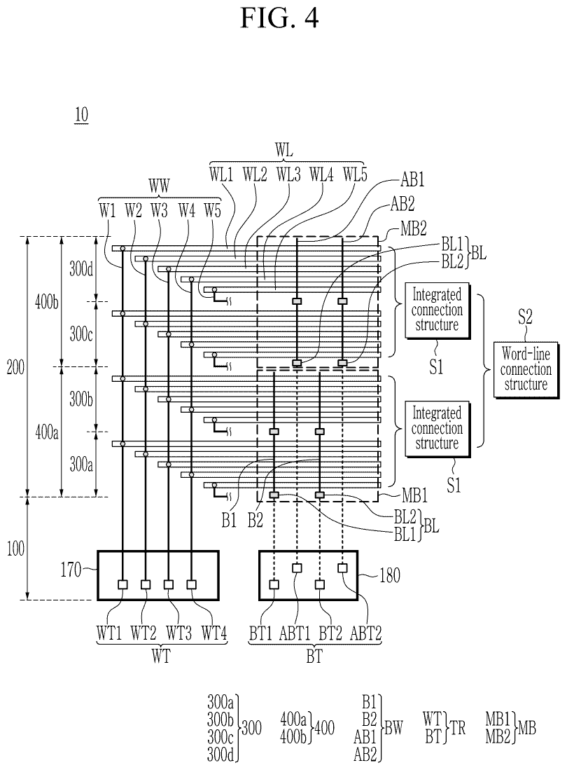

The circuit element 120 on the substrate 110 may include any of various circuit elements that control an operation of the memory cell structure in the cell region 200. For example, the circuit element 120 may constitute the peripheral circuit structure such as a decoder circuit (e.g., a decoder circuit 170 in FIG. 4 or a decoder circuit 1110 in FIG. 11), a page buffer (e.g., a page buffer 180 in FIG. 4 or a page buffer 1120 in FIG. 11), a logic circuit (e.g. a logic circuit 1130 in FIG. 11), or the like.

The circuit element 120 may include, for example, a plurality of transistors, but the embodiments are not limited thereto. For example, the circuit element 120 may include not only an active element such as the transistor or the like but also a passive element such as a capacitor, a resistor, an inductor, or the like.

The circuit wiring portion 160 on the substrate 110 may be electrically connected to the circuit element 120. In an embodiment, the circuit wiring portion 160 may include a plurality of wiring layers 162, a bonding structure 164, and a bonding insulation layer 166. The plurality of wiring layers 162 may be spaced apart from each other while interposing an insulation layer between them. The plurality of wiring layers 162 may be electrically connected by a contact via to form a desired path. The bonding structure 164 may be electrically connected to the plurality of wiring layers 162 and be disposed at a portion facing the cell region 200. The bonding insulation layer 166 may be disposed at a periphery of the bonding structure 164 at the portion facing the cell region 200.

The insulation layer of the circuit wiring portion 160 may include any of various insulating materials, and the wiring layer 162 or the contact via of the circuit wiring portion 160 may include any of various conductive materials. The bonding structure 164 and the bonding insulation layer 166 of the circuit region 100 will be described in detail.

The cell region 200 may include a gate stacking structure 220, a channel structure CH, an upper wiring portion 260, and a lower wiring portion 270. The cell region 200 may include a cell array region 202 and a connection region 204. The cell region 200 may include at least the gate stacking structure 220 and the channel structure CH that are disposed in the cell array region 202 as a memory cell structure. A structure that connects the memory cell structure to the circuit region 100 or an external circuit may be disposed in the cell array region 202 and/or the connection region 204.

In the specification, unless otherwise described, a portion that is disposed at an upper portion in a manufacturing process (e.g., a portion that is adjacent to a channel pad 244 or the upper wiring portion 260, or a portion that is opposite to a protruding portion CHP of the channel structure CH or the lower wiring portion 270) may be an upper portion. A portion that is disposed at a lower portion in a manufacturing process (e.g., a portion that is adjacent to the protruding portion CHP of the channel structure CH or the lower wiring portion 270 or a portion that is opposite to the channel pad 244 or the upper wiring portion 260) may be a lower portion. In this specification, the terms of the upper portion and the lower portion are used only to distinguish them from each other, and the embodiments are not limited thereto.

The gate stacking structure 220 may include a plurality of gate electrodes 230 while interposing a cell insulation layer 232 (e.g., an interlayer insulation layer 232m) therebetween. For example, a plurality of cell insulation layers 232 (e.g., a plurality of interlayer insulation layers 232m) and the plurality of gate electrodes 230 may be alternately stacked to each other. The channel structure CH may extend in an extension direction and pass through or penetrate the gate stacking structure 220. For example, the extension direction of the channel structure CH may be a thickness direction of the memory portion 300 (e.g., a direction perpendicular to the memory portion 300) or the Z-axis direction in the drawings.

The plurality of gate electrodes 230 may constitute a plurality of word lines WL (refer to FIG. 4), respectively. The gate electrode 230 may include any of various conductive materials. For example, the gate electrodes 230 may include or be formed of a semiconductor material, a metal material, metal nitride, or a combination thereof. The semiconductor material that is included in the gate electrodes 230 may include or be formed of polycrystalline semiconductor (e.g., polycrystalline silicon). The metal material that is included in the gate electrodes 230 may include or be formed of at least one of copper, aluminum, tungsten, nickel, gold, tin, manganese, cobalt, titanium, tantalum, ruthenium, or beryllium, or may include or be formed of an alloy including the above metal. The metal nitride that is included in the gate electrodes 230 may include or be formed of titanium nitride (TiN), tantalum nitride (TaN), or the like.

The cell insulation layer 232 may include a portion (e.g., the interlayer insulating layer 232m) disposed between the gate electrodes 230, and include a portion disposed on the gate stacking structure 220 in cell array region 202 and/or the connection region 204. The cell insulation layer 232 may include any of various insulating materials. For example, the cell insulation layer 232 may include or be formed of silicon oxide, silicon nitride, silicon oxynitride, a low dielectric constant material having a lower dielectric constant than silicon oxide, or a combination thereof.

The channel structure CH may include a channel layer 240, and a gate dielectric layer 250 on the channel layer 240 between the gate electrode 230 and the channel layer 240. The gate dielectric layer 250 between the gate electrode 230 and the channel layer 240 may include a tunneling layer 252, a charge storage layer 254, and a blocking layer 256 sequentially on the channel layer 240.

The channel structure CH may further include a core insulation layer 242 at an inside of the channel layer 240. In some embodiments, the core insulation layer 242 may be omitted. The channel structure CH may further include a channel pad 244 on the channel layer 240 and/or the core insulation layer 242. The channel pad 244 may cover an upper surface (a lower surface in FIG. 3) of the core insulation layer 242 and be disposed to be electrically connected to the channel layer 240.

Each channel structure CH may form one memory cell string, and a plurality of channel structures CH may be spaced apart from each other while forming rows and columns in a plan view. For example, a plurality of channel structures CH may be disposed to form any of various shapes such as a lattice shape, a zigzag shape, or the like in a plan view. The channel structure CH may have a pillar shape. For example, in a cross-sectional view, the channel structure CH may have an inclined side surface such that a width of the channel structure CH decreases toward the lower wiring portion 270 due to a high aspect ratio. However, the embodiments are not limited thereto, and an arrangement, a structure, a shape, or the like of the channel structure CH may be variously modified.

The channel layer 240 may include a semiconductor material (e.g., polycrystalline silicon). The core insulation layer 242 may include any of various insulating materials. For example, the core insulation layer 242 may include or be formed of silicon oxide, silicon nitride, silicon oxynitride, or a combination thereof. The channel pad 244 may include or be formed of a conductive material (e.g., polycrystalline silicon doped with a dopant), but the embodiments are not limited thereto.

The tunneling layer 252 may include or be formed of an insulating material that is capable of tunneling a charge (e.g., silicon oxide, silicon oxynitride, or the like). The charge storage layer 254 may be used as a data storage region, and the charge storage layer 254 may include polycrystalline silicon, silicon nitride, or the like. The blocking layer 256 may include an insulating material that is capable of preventing an undesirable flow of charge into the gate electrode 230. The blocking layer 256 may include or be formed of, for example, silicon oxide, silicon nitride, silicon oxynitride, a high dielectric constant material having a higher dielectric constant than silicon oxide, or a combination thereof. In an embodiment, the blocking layer 256 may include a first blocking layer 256a that includes a portion horizontally extending on the gate electrode 230, and a second blocking layer 256b that vertically extends between the first blocking layer 256a and the charge storage layer 254.

However, a material, a structure, or the like of the channel layer 240, the core insulation layer 242, the channel pad 244, or the gate dielectric layer 250 may be variously modified, and the embodiments are not limited thereto.

In an embodiment, the channel structure CH may include a protruding portion CHP protruding from a lower surface (an upper surface in FIG. 3) of the gate stacking structure 220. The gate dielectric layer 250 is not disposed at the protruding portion CHP, and the channel layer 240 disposed at the protruding portion CHP and a horizontal conductive layer 272a may be electrically connected to each other. However, the embodiments are not limited thereto, and any of various structures that electrically connect the channel structure CH and the horizontal conductive layer 272a may be applied.

In an embodiment, the gate stacking structure 220 may include a plurality of gate stacking portions (e.g., first and second gate stacking portions 221 and 222) that are sequentially stacked in the thickness direction of the memory portion 300 (the Z-axis direction in the drawings). Thereby, a number of stacked gate electrodes 230 may increase and thus a number of memory cells may increase with a stable structure. In FIG. 2, it is illustrated as an example that the gate stacking structure 220 includes the first and second gate stacking portions 221 and 222. However, the embodiments are not limited thereto. In some embodiments, the gate stacking structure 220 may include one gate stacking portion or three or more gate stacking portions.

When the plurality of gate stacking portions (e.g., first and second gate stacking portions 221 and 222) are provided as in the above, the channel structure CH may include a plurality of channel portions (e.g., first and second channel portions CH1 and CH2) that respectively pass through the plurality of gate stacking portions (e.g., the first and second gate stacking portions 221 and 222). The plurality of channel portions may be connected to each other. In a cross-sectional view, each of the plurality of channel portions (e.g., the first and second channel portions CH1 and CH2) may have an inclined side surface such that a width of each of the plurality of channel portions decreases toward the lower wiring portion 270 due to a high aspect ratio. A bent portion due to a difference in widths of the plurality of channel portions may be provided at a connection portion of the plurality of channel portions. In some embodiments, at least one of the plurality of channel portions (e.g., the first and second channel portions CH1 and CH2) may have an inclined side surface that continuously extends without the bent portion. In FIG. 3, it is illustrated as an example that each of the gate dielectric layer 250, the channel layer 240, and the core insulation layer 242 of the plurality of channel portions (e.g., the first and second channel portions CH1 and CH2) continuously extends to have an integral structure. In some embodiments, gate dielectric layers 250, channel layers 240, and core insulation layers 242 of the plurality of channel portions (e.g., the first and second channel portions CH1 and CH2) may be separately formed and be electrically connected to each other. In some embodiments, a separate channel pad may be additionally disposed at the connection portion of the plurality of channel portions (e.g., the first and second channel portions CH1 and CH2). As such, the embodiments are not limited to a shape of the plurality of channel portions (e.g., the first and second channel portions CH1 and CH2).

In an embodiment, the gate stacking structure 220 may be divided into a plurality of portions in a plan view by a separation structure 246. An upper separation region 248 may be disposed at an upper portion (a lower portion in FIG. 2) of the gate stacking structure 220. In a plan view, the separation structure 246 and/or the upper separation region 248 may extend in a first direction (a X-axis direction in the drawings). A plurality of separation structures 246 and/or a plurality of upper separation regions 248 may be spaced apart from each other at predetermined intervals in a second direction (a Y-axis direction in the drawings) that intersects (e.g., perpendicular to) the first direction.

By the separation structure 246, in a plan view, a plurality of gate stacking structures 220 may extend in the first direction (the X-axis direction in the drawings) and be spaced apart from each other at predetermined intervals in the second direction (the Y-axis direction in the drawings) that intersects the first direction. At least a partial portion of the gate stacking structure 220 divided by the separation structure 246 may constitute at least a partial portion of one memory cell block. However, the embodiments are not limited thereto, and a range of the memory cell block is not limited thereto.

For example, the separation structure 246 may pass through or penetrate the gate stacking structure 220 and extend to the horizontal conductive layer 272a or the lower wiring portion 270, and the upper separation region 248 may separate one or a part of the plurality of gate electrodes 230. The upper separation region 248 may be disposed between the separation structures 246. In a cross-sectional view, the separation structure 246 or the upper separation region 248 may extend to pass through or penetrate the gate stacking structure 220. For example, the extension direction of the separation structure 246 or the upper separation region 248 may be the thickness direction of the memory portion 300 (e.g., a direction perpendicular to the memory portion 300) or the Z-axis direction in the drawings.

It is illustrated as an example that the separation structure 246 has an inclined side surface such that a width of the separation structure 246 decreases toward the lower wiring portion 270 due to a high aspect ratio, but the embodiments are not limited thereto. The side surface of the separation structure 246 may be parallel to a vertical direction or the thickness direction, or a bent portion may be provided at a connection portion of the plurality of gate stacking portions (e.g., the first and second gate stacking portions 221 and 222).

Any of various insulating materials may be filled in at least a partial portion of the separation structure 246 and/or the upper separation region 248. For example, the separation structure 246 or the upper separation region 248 may include or be formed of an insulating material such as silicon oxide, silicon nitride, or silicon oxynitride. However, the embodiments are not limited thereto, and a structure, a shape, a material, or the like of the separation structure 246 or the upper separation region 248 may be variously modified.

The connection region 204, the upper wiring portion 260, the lower wiring portion 270, a gate contact portion 282, a source contact portion 284, and a penetrating plug 290 may be provided to connect the gate stacking structure 220 and the channel structure CH in the cell array region 202 to the circuit region 100 or the external circuit. The connection region 204 may be disposed at a periphery of the cell array region 202. At least a partial portion of the upper wiring portion 260, at least a partial portion of the lower wiring portion, the gate contact portion 282, the source contact portion 284, and/or the penetrating plug 290 may be disposed in the connection region 204.

The upper wiring portion 260 may be disposed on an upper surface (a lower surface in the drawings) of the gate stacking structure 220, and the lower wiring portion 270 may be disposed on a lower surface (an upper surface in the drawings) of the gate stacking structure 220.

In an embodiment, the upper wiring portion 260 may include any of members that electrically connect the gate electrodes 230, the channel structure CH, the gate contact portion 282, the source contact portion 284, the penetrating plug 290, and/or the lower wiring portion 270 to the circuit region 100, the external circuit, or another memory portion 300. In an embodiment, the upper wiring portion 260 may include a plurality of upper wiring layers 262, an upper bonding structure 264, and an upper bonding insulation layer 266. The plurality of upper wiring layers 262 may be spaced apart from each other while interposing an insulation layer therebetween and may be electrically connected by a contact via to form a desired path. The upper bonding structure 264 may be electrically connected to the plurality of upper wiring layers 262. The upper bonding insulation layer 266 may be disposed at a periphery of the upper bonding structure 264. The upper bonding structure 264 and the upper bonding insulation layer 266 of the upper wiring portion 260 may be disposed at an upper surface (a lower surface in FIG. 1) of the memory portion 300.

For example, the upper wiring layer 262 may include bit lines BL. The bit line 182 may extend in the second direction (the Y-axis direction in the drawings) that intersects (e.g., perpendicular to) the first direction (the X-axis direction in the drawings), which is the extension direction of the gate electrode 230. The bit line BL may be electrically connected to the channel structure CH (e.g., the channel pad 244). The upper wiring layer 262 may include a wiring portion (e.g., a wiring layer or a contact via) that is electrically connected to the bit lines BL, the gate contact portion 282, the source contact portion 284, and the penetrating plug 290.

In an embodiment, the lower wiring portion 270 may include any of members that electrically connect the gate electrodes 230, the channel structure CH, the source contact portion 284, the penetrating plug 290, and/or the upper wiring portion 260 to the circuit region 100, the external circuit, or another memory portion 300. In an embodiment, the lower wiring portion 270 may include a plurality of lower wiring layers 272, a lower bonding structure 274, and a lower bonding insulation layer 276. The plurality of lower wiring layers 272 may be spaced apart from each other while interposing an insulation layer therebetween and be electrically connected by a contact via to form a desired path. The lower bonding structure 274 may be electrically connected to the plurality of lower wiring layers 272. The lower bonding insulation layer 276 may be disposed at a periphery of the lower bonding structure 274. The lower bonding structure 274 and the lower bonding insulation layer 276 of the lower wiring portion 270 may be disposed at a lower surface (an upper surface in FIG. 1) of the memory portion 300.

For example, the lower wiring layer 272 may include a horizontal conductive layer 272a that is electrically connected to (e.g., is in contact with) the protruding portion CHP of the channel structure CH (e.g., the channel layer 240). The lower wiring layer 272 may include a wiring portion (e.g., a wiring layer or a contact via) that is electrically connected to the horizontal conductive layer 272a, the source contact portion 284, and the penetrating plug 290.

The horizontal conductive layer 272a may have any of various structures that are electrically connected to the channel structure CH to provide an electrical connection passage, and the embodiment are not limited thereto. In the drawings, it is illustrated as an example that the horizontal conductive layer 272a has a thickness greater than a height of the protruding portion CHP of the channel structure CH. However, the embodiment are not limited thereto. In some embodiments, the horizontal conductive layer 272a may have a thickness same as or less than the height of the protruding portion CHP of the channel structure CH, and the horizontal conductive layer 272a may have a curve or a step that corresponds to the protruding portion CHP of the channel structure CH.

The insulation layer of the upper wiring portion 260 and/or the insulation layer of the lower wiring portion 270 may include or be formed of any of various insulating materials. The upper wiring layer 262 or the contact via that is included in the upper wiring portion 260 and/or the lower wiring layer 272 or the contact via that is included in the lower wiring portion 270 may include or be formed of any of various conductive materials.

For example, the horizontal conductive layer 272a may include or be formed of any of various conductive materials. For example, the horizontal conductive layer 272a may include or be formed of a semiconductor material or a metal material. The semiconductor material that is included in the horizontal conductive layer 272a may include or be formed of polycrystalline semiconductor (e.g., polycrystalline silicon). The metal material that is included in the horizontal conductive layer 272a may include or be formed of at least one of copper, aluminum, tungsten, nickel, gold, tin, manganese, cobalt, titanium, tantalum, ruthenium, or beryllium, or may include or be formed of an alloy including the above metal. The horizontal conductive layer 272a may include a single layer, or may include a plurality of layers or a plurality of portions that include different materials.

In an embodiment, in the circuit region 100 and the memory portion 300 that are adjacent to each other, the bonding structure 164 and the upper or lower bonding structure 264 or 274 adjacent to the bonding structure 164 may be bonded by metal bonding, and the bonding insulation layer 166 and the upper or lower bonding insulation layer 266 or 276 adjacent to the bonding insulation layer 166 may be bonded by insulation-layer bonding. Thereby, the circuit region 100 and the memory portion 300 may be bonded by hybrid bonding. In FIG. 1, it is illustrated as example that the bonding structure 164 and the upper bonding structure 264 are bonded by the metal bonding, and the bonding insulation layer 166 and the upper bonding insulation layer 266 are bonded by the insulation-layer bonding. However, the embodiment are not limited thereto.

In an embodiment, in two memory portions 300 that are adjacent to each other, two adjacent boding structures (e.g., the upper bonding structure 264 and/or the lower bonding structure 274) may be bonded by metal bonding, and two adjacent bonding insulation layers (e.g., the upper bonding insulation layer 266 and/or the lower bonding insulation layer 276) may be bonded by insulation-layer bonding. Thereby, two memory portions 300 that are adjacent to each other may be bonded by hybrid bonding. In FIG. 1, it is illustrated as example that the lower bonding structure 274 that is included in one memory portion 300 and the upper bonding structure 264 that is included in another memory portion 300 and is adjacent to the lower bonding structure 274 are bonded by the metal bonding, and the lower bonding insulation layer 276 that is included in one memory portion 300 and the upper bonding insulation layer 266 that is included in another memory portion 300 and is adjacent to the lower bonding insulation layer 276 are bonded by the insulation-layer bonding. However, the embodiment are not limited thereto.

For example, the bonding structure 164, the upper bonding structure 264, and/or the lower bonding structure 274 may include or be formed of at least one of copper, aluminum, tungsten, nickel, gold, tin, manganese, cobalt, titanium, tantalum, ruthenium, or beryllium, or include or be formed of an alloy including the above material. For example, the bonding structure 164, the upper bonding structure 264, and/or the lower bonding structure 274 may include or be formed of copper. Thereby, the circuit region 100 and the memory portion 300 or two adjacent memory portions 300 may be bonded to each other (e.g., may be bonded to each other by direct contact) by copper-to-copper bonding. However, the embodiment are not limited thereto.

For example, the bonding insulation layer 166, the upper bonding insulation layer 266, and/or the lower bonding insulation layer 276 may include a same insulating material (e.g., silicon carbonitride (SiCNx)) at an insulation layer bonding surface. However, the embodiments are not limited thereto, and the bonding insulation layer 166, the upper bonding insulation layer 266, and/or the lower bonding insulation layer 276 may include or be formed of any of various insulating materials.

In the connection region 204, the plurality of gate electrodes 230 may extend in the first direction (the X-axis direction in the drawings). In the connection region 204, extension lengths of the plurality of gate electrodes 230 may sequentially decrease far away from the lower wiring portion 270. For example, the plurality of gate electrodes 230 may have a stair shape in one direction or a plurality of directions in the connection region 204. In the connection region 204, a plurality of gate contact portions 282 may pass through or penetrates the cell insulation layer 232 and that are electrically connected to the plurality of gate electrodes 230, respectively, extended in the connection region 204. For example, the gate contact portions 282 may electrically connect the gate electrodes 230 to at least one of the upper wiring portion 260 or the lower wiring portion 270.

The source contact portion 284 may be electrically connected to the horizontal conductive layer 272a that constitutes at least a partial portion of a common source line. For example, in FIG. 1, it is illustrated as example that the source contact portion 284 includes a conductive portion and an side insulation layer to have a same shape as the penetrating plug 290, and the lower wiring layer 272 includes a wiring portion that electrically connects the source contact portion 284 and the horizontal conductive layer 272a. However, the embodiments are not limited thereto, and a shape of the source contact portion 284, and/or an electrical connection structure of the source contact portion 284 and the horizontal conductive layer 272a may be variously modified.

The penetrating plug 290 may pass through or penetrate the gate stacking structure 220 or may be disposed outside the gate stacking structure 220. The penetrating plug 290 may electrically connect the upper wiring portion 260 and the lower wiring portion 270 in the memory portion 300. More particularly, the penetrating plug 290 may be configured to electrically connect driving lines (e.g., word lines WL and/or bit lines BL) that are electrically connected in the plurality of memory portions 300.

The penetrating plug 290 may include a conductive portion 290a, and a side insulation layer 290b that surrounds at least a partial portion of a side surface of the conductive portion 290a. The upper wiring portion 260 and the lower wiring portion 270 may be electrically connected by the conductive portion 290a, and the penetrating plug 290 may be electrically insulated from the gate stacking structure 220 and/or the horizontal conductive layer 272a by the side insulation layer 290b. However, the embodiments are not limited thereto, and the penetrating plug 290 may include the conductive portion 290a without the side insulation layer 290b in a case that the penetrating plug 290 passes through or penetrates the cell insulation layer 232 outside the gate stacking structure 220.

In an embodiment, the penetrating plug 290 may include a word plug 292 and/or a bit plug 294. The word plug may be configured to electrically connect corresponding gate electrodes 230 (e.g., corresponding plurality of word lines WL) that correspond to each other in the plurality of memory portions 300. The bit plug 294 may be configured to electrically connect corresponding bit lines BL that correspond to each other in the plurality of memory portions 300.

In an embodiment, the word plug 292 may include a plurality of word plugs 292 that are electrically connected to the plurality of gate electrodes 230 (e.g., the plurality of word lines WL), respectively. According to the wiring connection structure of the plurality of memory portions 300, with respect to the corresponding gate electrodes 230 (e.g., the corresponding word lines WL) BL in the plurality of memory portions 300,, one word plug 292 or a plurality of word plugs 292 may be provided in each memory portion 300,.

In an embodiment, the bit plug 294 may include a plurality of bit plugs 294 that are electrically connected to the plurality of bit lines BL, respectively. According to the wiring connection structure of the plurality of memory portions 300, with respect to the corresponding bit lines BL in the plurality of memory portions 300, one bit plug 294 or a plurality of bit plugs 294 may be provided in each memory portion 300.

In FIG. 1, it is illustrated as example that the word plug 292 and the bit plug 294 may have a same shape or structure, but the embodiments are not limited thereto.

In an embodiment, the cell region 200 and the circuit region 100 may be electrically connected to each other by the upper wiring portion 260 and the lower wiring portion 270, the gate contact portion 282, the source contact portion 284, and the penetrating plug 290 of the memory portion 300, and the circuit wiring portion 160 of the circuit region 100. In some embodiments, an input/output pad that is electrically connected to the upper wiring portion 260 or the lower wiring portion 270 and/or an input/output pad that is electrically connected to the circuit region 100 may be further included.

Referring to FIG. 4 together with FIG. 1, a wiring connection structure of the driving lines (i.e., the word lines WL and the bit lines BL) of the plurality of memory portions 300 that are included in the semiconductor device 10 will be described in detail.

FIG. 4 conceptually illustrates a wiring connection structure of the semiconductor device 10 illustrated in FIG. 1. In FIG. 4, a word connection wiring WW is illustrated as a solid line, and a portion where the word line WL and the word connection wiring WW are electrically connected to each other is illustrated as a circle. In FIG. 4, a bit line BL is illustrated as a rectangle, a portion of a bit connection wiring BW that is electrically connected to the bit line BL and includes the channel structure CH is illustrated as a solid line, and a portion of the bit connection wiring BW that is electrically connected to the bit line BL and does not include the channel structure CH is illustrated as a dotted line.

For a clear understanding and simple illustration, in FIG. 4 and the description, in each memory portion 300, it is illustrated and described as an example that a plurality of bit lines BL include first and second bit lines BL1 and BL2, and a plurality of word lines WL include first to fifth word lines WL1, WL2, WL3, WL4, and WL5. In FIG. 4, it is illustrated as example that positions of the first and second bit lines BL1 and BL2 in a first memory group 400a are different from positions of the first and second bit lines BL1 and BL2 in a second memory group 400b, but the embodiments are not limited thereto.

Referring to FIG. 1 and FIG. 4, in an embodiment, the plurality of memory portions 300 that are included in the cell region 200 may be grouped into a plurality of memory groups 400. Each memory group 400 may include a plurality of memory portions 300. That is, the cell region 200 may include a plurality of memory groups 400, and each of the plurality of memory groups 400 may include a plurality of memory portions 300.

For a clear understanding and simple illustration, in the drawings and the description, it is illustrated and described as an example that the plurality of memory groups 400 includes a first memory group 400a and a second memory group 400b, the first memory group 400a includes a first memory portion 300a and a second memory portion 300b sequentially bonded on or disposed on the circuit region 100, and the second memory group 400b includes a third memory portion 300c and a fourth memory portion 300d sequentially bonded on or disposed on the first memory group 400a. However, the embodiments are not limited thereto, and three or more memory groups 400 may be included, and/or each memory group 400 may include three or more memory portions 300.

In an embodiment, the plurality of memory portions 300 that are included in each memory group 400 may be electrically connected to have a first wiring connection structure S1, and the plurality of memory groups 400 may be electrically connected to have a second wiring connection structure S2 that is different from the first wiring connection structure S1.

Each memory portion 300 may include driving lines that include a plurality of word lines WL and a plurality of bit lines BL. The plurality of word lines WL may be formed of the plurality of gate electrodes 230, and may extend in the first direction (the X-axis direction in the drawings). The plurality of bit lines BL may be electrically connected to the plurality of channel structure CH, and may extend in the second direction (the Y-axis direction in the drawings) that intersects (e.g., perpendicular to) the first direction.

A connection structure of the driving lines (i.e., the word lines WL and/or the bit lines BL) in the first wiring connection structure S1 may be different form a connection structure of the driving lines (i.e., the word lines WL and/or the bit lines BL) in the second wiring connection structure S2.

For example, the first wiring connection structure S1 may be one of a word-line connection structure, a bit-line connection structure, and an integrated connection structure, and the second wiring connection structure S2 may be another one of the word-line connection structure, the bit-line connection structure, and the integrated connection structure.

In the word-line connection structure, in the plurality of memory portions 300 or the plurality of memory groups 400, corresponding word lines WL may be electrically connected to each other, and corresponding bit lines BL may not be electrically connected and may be provided individually or independently.

For example, in the word-line connection structure, in the plurality of memory portions 300 or the plurality of memory groups 400, the corresponding word lines WL may be electrically connected to a same wiring, and/or may be electrically connected to a same transistor TR. For example, in the plurality of memory portions 300 or the plurality of memory groups 400, at least a part of the plurality of word lines WL (e.g., the corresponding word lines WL) that are included may be merged, integrated, or shared, and a same signal may be applied to the at least the part of the plurality of word lines WL (e.g., the corresponding word lines WL). In the plurality of memory portions 300 or the plurality of memory groups 400, the corresponding bit lines BL may be connected to different wirings and/or different transistors TR, and/or different signals may be applied to the corresponding bit lines BL.

In the bit-line connection structure, in the plurality of memory portions 300 or the plurality of memory groups 400, corresponding bit lines BL may be electrically connected to each other, and corresponding word lines WL may not be electrically connected and may be provided individually or independently.

For example, in the bit-line connection structure, in the plurality of memory portions 300 or the plurality of memory groups 400, the corresponding bit lines BL may be electrically connected to a same wiring, and/or may be electrically connected to a same transistor TR. For example, in the plurality of memory portions 300 or the plurality of memory groups 400, the plurality of bit lines BL (e.g., the corresponding bit lines BL) may be merged, integrated, or shared, and a same signal may be applied to the plurality of bit lines BL (e.g., the corresponding bit lines BL). In the plurality of memory portions 300 or the plurality of memory groups 400, the corresponding word lines WL may be connected to different wirings and/or different transistors TR, and/or different signals may be applied to the corresponding word lines WL.

In the integrated connection structure, in the plurality of memory portions 300 or the plurality of memory groups 400, corresponding word lines WL may be electrically connected to each other, and corresponding bit lines BL may be electrically connected to each other.

For example, in the integrated connection structure, in the plurality of memory portions 300 or the plurality of memory groups 400, the corresponding word lines WL may be electrically connected to a same wiring, and/or may be electrically connected to a same transistor TR. For example, in the plurality of memory portions 300 or the plurality of memory groups 400, at least a part of the plurality of word lines WL (e.g., the corresponding word lines WL) that are included may be merged, integrated, or shared, and a same signal may be applied to the at least the part of the plurality of word lines WL (e.g., the corresponding word lines WL). In the integrated connection structure, in the plurality of memory portions 300 or the plurality of memory groups 400, the corresponding bit lines BL may be electrically connected to a same wiring, and/or may be electrically connected to a same transistor TR. For example, in the plurality of memory portions 300 or the plurality of memory groups 400, the plurality of bit lines BL (e.g., the corresponding bit lines BL) may be merged, integrated, or shared, and a same signal may be applied to the plurality of bit lines BL (e.g., the corresponding bit lines BL).

As illustrated in FIG. 4, in an embodiment, the plurality of memory portions 300 that are included in each memory group 400 may be electrically connected to have the first wiring connection structure S1, which is the integrated connection structure, and the plurality of memory groups 400 may be electrically connected to have the second wiring connection structure S2, which is the word-line connection structure.

The word lines WL that are included in each memory portion 300 may be electrically connected to the word transistors WT through the word connection wirings WW, and the bit lines BL that are included in each memory portion 300 may be electrically connected to the bit transistors BT through the bit connection wirings BW.

In an embodiment, since the plurality of memory portions 300 that are included in each memory group 400 may be electrically connected to have the integrated connection structure, the word connection wirings WW may be shared in the first and second memory portions 300a and 300b that are included in the first memory group 400a, and the word connection wirings WW may be shared in the third and the fourth memory portion 300c and 300d that are included in the second memory group 400b. Since the plurality of memory groups 400 may be electrically connected to have the word-line connection structure, the word connection wirings WW may be shared in the first memory group 400a and the second memory group 400b. That is, the plurality of word connection wirings WW may be shared in the first to fourth memory portions 300a, 300b, 300c, and 300d.

For example, a plurality of first word lines WL1 (e.g., corresponding word lines WL) that are included in the first to fourth memory portions 300a, 300b, 300c, and 300d and correspond to each other may be electrically connected to a same wiring (e.g., a first word connection wiring W1), and/or may be electrically connected to a same word transistors WT (e.g., a first word transistor WT1). That is, the plurality of first word lines WL1 (e.g., corresponding word lines WL) that are included in the first to fourth memory portions 300a, 300b, 300c, and 300d and correspond to each other may be merged, integrated, or shared, and/or a same signal may be applied to the plurality of first word lines WL1 (e.g., corresponding word lines WL) that are included in the first to fourth memory portions 300a, 300b, 300c, and 300d and correspond to each other.

A plurality of second word lines WL2 (e.g., corresponding word lines WL) that are included in the first to fourth memory portions 300a, 300b, 300c, and 300d and correspond to each other may be electrically connected to a same wiring (e.g., a second word connection wiring W2), and/or may be electrically connected to a same word transistors WT (e.g., a second word transistor WT2). That is, the plurality of second word lines WL2 (e.g., corresponding word lines WL) that are included in the first to fourth memory portions 300a, 300b, 300c, and 300d and correspond to each other may be merged, integrated, or shared, and/or a same signal may be applied to the plurality of second word lines WL2 (e.g., corresponding word lines WL) that are included in the first to fourth memory portions 300a, 300b, 300c, and 300d and correspond to each other.

A plurality of third word lines WL3 (e.g., corresponding word lines WL) that are included in the first to fourth memory portions 300a, 300b, 300c, and 300d and correspond to each other may be electrically connected to a same wiring (e.g., a third word connection wiring W3), and/or may be electrically connected to a same word transistors WT (e.g., a third word transistor WT3). That is, the plurality of third word lines WL3 (e.g., corresponding word lines WL) that are included in the first to fourth memory portions 300a, 300b, 300c, and 300d and correspond to each other may be merged, integrated, or shared, and/or a same signal may be applied to the plurality of third word lines WL3 (e.g., corresponding word lines WL) that are included in the first to fourth memory portions 300a, 300b, 300c, and 300d and correspond to each other.

A plurality of fourth word lines WL4 (e.g., corresponding word lines WL) that are included in the first to fourth memory portions 300a, 300b, 300c, and 300d and correspond to each other may be electrically connected to a same wiring (e.g., a fourth word connection wiring W4), and/or may be electrically connected to a same word transistors WT (e.g., a fourth word transistor WT4). That is, the plurality of fourth word lines WL4 (e.g., corresponding word lines WL) that are included in the first to fourth memory portions 300a, 300b, 300c, and 300d and correspond to each other may be merged, integrated, or shared, and/or a same signal may be applied to the plurality of fourth word lines WL4 (e.g., corresponding word lines WL) that are included in the first to fourth memory portions 300a, 300b, 300c, and 300d and correspond to each other.

In an embodiment, the corresponding word lines WL in the first to fourth memory portions 300a, 300b, 300c, and 300d may electrically connected to each other via the gate contact portion 282 and the word plug 292. For example, the gate contact portions 282 and the word plugs 292, the upper wiring portion 260, the lower wiring portion 270, and the circuit wiring portion 160 may be electrically connected to each other to form the word connection wiring WW.

In FIG. 1, it is illustrated as example that a portion in the fourth memory portion 300d, a portion in the third memory portion 300c, a portion in the second memory portion 300b, a portion in the first memory portion 300a, and the circuit wiring portion 160 are electrically connected to each other to form one word connection wiring WW. The portion in the fourth memory portion 300d may include the gate contact portion 282 and a fourth upper wiring portion 260d that are electrically connected to the word line WL. The portion in the third memory portion 300c may include the gate contact portion 282, the word plug 292, a third lower wiring portion 270c, and a third upper wiring portion 260c that are electrically connected to the word line WL. The portion in the second memory portion 300b may include the gate contact portion 282, the word plug 292, a second lower wiring portion 270b, and a second upper wiring portion 260b that are electrically connected to the word line WL. The portion in the first memory portion 300a may include the gate contact portion 282, the word plug 292, a first lower wiring portion 270a, and a first upper wiring portion 260a that are electrically connected to the word line WL. In two adjacent memory portions 300, two bonding structures (e.g., the upper bonding structure 264 and/or the lower bonding structure 274) that are electrically connected to the word plug 292 may be bonded to each other. In the circuit region 100 and the memory portion 300 adjacent to each other, the bonding structure 164 and the upper or lower bonding structure 264 or 274 may be bonded to each other.

However, the embodiments are not limited thereto, and any of various structures where the word connection wiring WW is shared in the first to fourth memory portions 300a, 300b, 300c, and 300d may be applied. For example, the gate contact portion 282 may entirely pass through or penetrate the gate stacking structure 220 to be electrically connected to a connection gate electrode of the plurality of gate electrodes 230 and to be electrically insulated from remained gate electrodes other than the connection gate electrode by an insulation layer. In this case, the corresponding word lines WL in the first to fourth memory portions 300a, 300b, 300c, and 300d may electrically connected to each other by the gate contact portions 282 without the word plug 292. Other various modifications are possible.

In an embodiment, fifth word connection wirings W5 that are connected to a plurality of fifth word lines WL5, respectively, which are included in the first to fourth memory portions 300a, 300b, 300c, and 300d may be individually or independently provided not to be electrically connected to each other. That is, the plurality of fifth word lines WL5 that are included in the first to fourth memory portions 300a, 300b, 300c, and 300d may be connected to different word transistors WT, or different signals may be applied to the plurality of fifth word lines WL5 that are included in the first to fourth memory portions 300a, 300b, 300c, and 300d. For a clear understanding and simple illustration, in FIG. 4, the plurality of fifth word connections wirings W5 that are electrically connected to the plurality of fifth word lines WL5, respectively, are schematically illustrated, and a plurality of word transistors that are electrically connected to the plurality of fifth word lines WL5 are omitted. To drive the plurality of memory portions 300 separately or individually, the plurality of fifth word lines WL5 may have the above structure.

However, the embodiments are not limited thereto, and at least two of the plurality of fifth word lines WL5 that are included in the first to fourth memory portions 300a, 300b, 300c, and 300d may be electrically connected to each other.

In an embodiment, since the plurality of memory portions 300 that are included in each memory group 400 may be electrically connected to have the integrated connection structure, the bit connection wirings BW may be shared in the first and second memory portions 300a and 300b that are included in the first memory group 400a, and the bit connection wirings BW may be shared in the third and the fourth memory portion 300c and 300d that are included in the second memory group 400b. Since the plurality of memory groups 400 may be electrically connected to have the word-line connection structure, the bit connection wirings BW of the first memory group 400a and the bit connection wirings BW of the second memory group 400b may be individually or independently provided not to be electrically connected to each other, or may be electrically connected to different bit transistors BT.

That is, the plurality of bit connection wirings BW may include bit connection wirings BW (e.g., first and second bit connection wirings B1 and B2) that are shared in one of the plurality of memory groups 400 (e.g., the first and second memory portions 300a and 300b that are included in the first memory group 400a) and bit connection wirings BW (e.g., first and second additional bit connection wirings AB1 and AB2) that are shared in another one of the plurality of memory groups 400 (e.g., the third and fourth memory portions 300c and 300d that are included in the second memory group 400b).

For example, a plurality of first bit lines BL1 (e.g. corresponding bit lines BL) that are included in the first and second memory portions 300a and 300b and correspond to each other may be electrically connected to a same wiring (e.g., the first bit connection wiring B1), and/or may be electrically connected to a same bit transistor BT (e.g., a first bit transistor BT1). That is, the plurality of first bit lines BL1 (e.g. corresponding bit lines BL) that are included in the first and second memory portions 300a and 300b and correspond to each other may be merged, integrated, or shared and a same signal may be applied to the plurality of first bit lines BL1 (e.g. corresponding bit lines BL) that are included in the first and second memory portions 300a and 300b and correspond to each other.

A plurality of second bit lines BL2 (e.g. corresponding bit lines BL) that are included in the first and second memory portions 300a and 300b and correspond to each other may be electrically connected to a same wiring (e.g., the second bit connection wiring B2), and/or may be electrically connected to a same bit transistor BT (e.g., a second bit transistor BT2). That is, the plurality of second bit lines BL2 (e.g. corresponding bit lines BL) that are included in the first and second memory portions 300a and 300b and correspond to each other may be merged, integrated, or shared, and a same signal may be applied to the plurality of second bit lines BL2 (e.g. corresponding bit lines BL) that are included in the first and second memory portions 300a and 300b and correspond to each other.

For example, the plurality of first bit lines BL1 (e.g. corresponding bit lines BL) that are included in the third and fourth memory portions 300c and 300d and correspond to each other may be electrically connected to a same wiring (e.g., the first additional bit connection wiring AB1), and/or may be electrically connected to a same bit transistor BT (e.g., a first additional bit transistor ABT1). That is, the plurality of first bit lines BL1 (e.g. corresponding bit lines BL) that are included in the third and fourth memory portions 300c and 300d and correspond to each other may be merged, integrated, or shared, and a same signal may be applied to the plurality of first bit lines BL1 (e.g. corresponding bit lines BL) that are included in the third and fourth memory portions 300c and 300d and correspond to each other.

The plurality of second bit lines BL2 (e.g. corresponding bit lines BL) that are included in the third and fourth memory portions 300c and 300d and correspond to each other may be electrically connected to a same wiring (e.g., the second additional bit connection wiring AB2), and/or may be electrically connected to a same bit transistor BT (e.g., a second additional bit transistor ABT2). That is, the plurality of second bit lines BL2 that are included in the third and fourth memory portions 300c and 300d and correspond to each other may be merged, integrated, or shared, and a same signal may be applied to the plurality of second bit lines BL2 that are included in the third and fourth memory portions 300c and 300d and correspond to each other.

In an embodiment, the corresponding bit lines BL in the first and second memory portions 300a and 300b may electrically connected to each other via the bit plug 294, and the corresponding bit lines BL in the third and fourth memory portions 300c and 300d may electrically connected to each other via the bit plug 294. For example, the bit plug 292, the upper wiring portion 260, the lower wiring portion 270, and the circuit wiring portion 160 may be electrically connected to each other to form the bit connection wiring BW.

In FIG. 1, it is illustrated as example that a portion in the second memory portion 300b, a portion in the first memory portion 300, and the circuit wiring portion 160 are electrically connected to each other to form one bit connection wiring BW (e.g., the first or second bit connection wiring B1 or B2). The portion in the second memory portion 300b may include the second upper wiring portion 260b that is electrically connected to the bit line BL. The portion in the first memory portion 300a may include a first bit plug 294a, the first lower wiring portion 270a, and the first upper wiring portion 260a that are electrically connected to the bit line BL. In two adjacent memory portions 300, two bonding structures (e.g., the upper bonding structure 264 and/or the lower bonding structure 274) that are electrically connected to the bit plug 294 may be bonded to each other. In the circuit region 100 and the memory portion 300 adjacent to each other, the bonding structure 164 and the upper or lower bonding structure 264 or 274 may be bonded to each other.

In FIG. 1, it is illustrated as example that a portion in the fourth memory portion 300d, a portion in the third memory portion 300c, a portion in the second memory portion 300b, a portion in the first memory portion 300a, and the circuit wiring portion 160 are electrically connected to each other to form one bit connection wiring BW (e.g., the first or second additional bit connection wiring AB1 or AB2). The portion in the fourth memory portion 300d may include the fourth upper wiring portion 260d that is electrically connected to the bit line BL. The portion in the third memory portion 300c may include a second bit plug 294b, the third lower wiring portion 270c, and the third upper wiring portion 260c that are electrically connected to the bit line BL. The portion in the second memory portion 300b may include a second bit plug 294b, the second lower wiring portion 270b, and the second upper wiring portion 260b that are electrically connected to the bit line BL. The portion in the first memory portion 300a may include a second bit plug 294b, the first lower wiring portion 270a, and the first upper wiring portion 260a that are electrically connected to the bit line BL. In two adjacent memory portions 300, two bonding structures (e.g., the upper bonding structure 264 and/or the lower bonding structure 274) that are electrically connected to the bit plug 294 may be bonded to each other. In the circuit region 100 and the memory portion 300 adjacent to each other, the bonding structure 164 and the upper or lower bonding structure 264 or 274 may be bonded to each other.

However, the embodiments are not limited thereto. Any of various structure where the first and/or second bit connection wiring B1 and/or B2 is shared in the first and second memory portions 300a and 300b may be applied. Any of various structure where the first and/or second additional bit connection wiring AB1 and/or AB2 is shared in the third and fourth memory portions 300c and 300b may be applied.

In an embodiment, a source connection wiring may be shared in the first to fourth memory portions 300a, 300b, 300c, and 300d. For example, a plurality of horizontal conductive layers 272a that are included in the first to fourth memory portions 300a, 300b, 300c, and 300d may be electrically connected to a same wing (e.g., a source connection wiring), and/or may be electrically connected to a same transistor TR. That is, the plurality of horizontal conductive layers 272a that are included in the first to fourth memory portions 300a, 300b, 300c, and 300d may be merged, integrated, or shared, and/or a same signal may be applied to the plurality of horizontal conductive layers 272a that are included in the first to fourth memory portions 300a, 300b, 300c, and 300d.

In an embodiment, the plurality of horizontal conductive layers 272a that are included in the first to fourth memory portions 300a, 300b, 300c, and 300d may be electrically connected to each other via the source contact portions 284. For example, the source contact portions 284, the upper wiring portion 260, the lower wiring portion 270, and the circuit wiring portion 160 may be electrically connected to each other to form the source connection wiring.

In FIG. 1, it is illustrated as example that the source contact portions 284, the lower wiring portion 270, and the upper wiring portion 260 that are electrically connected to the horizontal conductive layer 272a in each of the first to fourth memory portions 300a, 300b, 300c, and 300d, and the circuit wiring portion 160 are electrically connected to each other to form one source connection wiring line. For example, each of the first to fourth lower wiring 270a, 270b, 270c, and 270d that are included in the first to fourth memory portions 300a, 300b, 300c, and 300d, respectively, may include a wiring that connects the source contact portion 284 and the horizontal conductive layer 272a. In two adjacent memory portions 300, two bonding structures (e.g., the upper bonding structure 264 and/or the lower bonding structure 274) that are electrically connected to the source contact portion 284 may be bonded to each other. In the circuit region 100 and the memory portion 300 adjacent to each other, the bonding structure 164 and the upper or lower bonding structure 264 or 274 may be bonded to each other.

However, the embodiment are not limited thereto. In some embodiments, any of various structures where the plurality of horizontal conductive layers 272a are shared in the first to fourth memory portions 300a, 300b, 300c, and 300d may be applied. In some embodiments, at least two of the plurality of horizontal conductive layers 272a that are included in the first to fourth memory portions 300a, 300b, 300c, and 300d may be individually or independently provided not to be electrically connected to each other.

In an embodiment, a memory cell block MB may be associated with a part of the plurality of memory groups to be associated with one or more memory portions. For example, a memory cell block MB may correspond to at least one memory group, partially correspond to the plurality of memory portions 300 in the memory group, and/or correspond to one or more memory portions of the plurality of memory portions in memory group. For example, the memory cell block MB may correspond to each memory group 400. A first memory cell block MB1 may correspond to the first and second memory portions 300a and 300b, and a second memory cell block MB2 may correspond to the third and fourth memory portions 300c and 300d.

According to an embodiment, the plurality of memory portions 300 that are included in each memory group 400 may be electrically connected to have the first wiring connection structure S1, and the plurality of memory groups 400 may be electrically connected to have the second wiring connection structure S2 different from the first wiring connection structure S1, thereby enhancing performance and productivity of the semiconductor device 10 together. That is, by an organic connection of a sub-connection (e.g., a primary connection that electrically connects the plurality of memory portions 300) and a super-connection (e.g., a secondary connection that electrically connects the plurality of memory groups 400), the performance and the productivity of the semiconductor device 10 may be enhanced in balance.

As in the above, in an embodiment, the plurality of memory portions 300 that are included in each memory group 400 may be electrically connected to have the integrated connection structure, and the plurality of memory groups 400 may be electrically connected to have the word-line connection structure. Thereby, lengths of the gate electrodes 230 in the connection region 204 may be reduced and driving time of the semiconductor device 10 may be reduced. By reducing a size of the memory cell block MB, power may be reduced, a disturbance phenomenon may be reduced, and a ratio of a spare memory cell block provided to smoothly drive the semiconductor device 10 may be reduced. Further, a size of the semiconductor device 10 may be reduced by reducing a size of the connection region 204, and a wiring structure of the upper wiring portion 260 that is connected to the bit lines BL may be simplified. Particularly, in an embodiment, by effectively reducing the lengths of the gate electrodes 230 in the connection region 204 and the size of the connection region 204, performance of the semiconductor device 10 may be effectively enhanced and a size of the semiconductor device 10 may be effectively reduced.

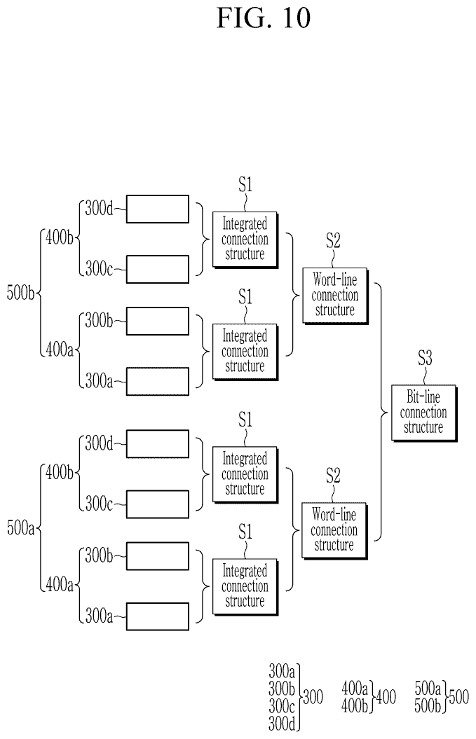

In the description, it is described as an example that the plurality of memory portions 300 are electrically connected to each other by the primary connection and the secondary connection, but the embodiments are not limited thereto. The plurality of memory portions 300 may be electrically connected to each other by a multi-connection structure that includes two or more connection structures. An embodiment where a plurality of memory portions 300 are electrically connected to each other by a primary connection, a secondary connection, and a tertiary connection will be described in detail with reference to FIG. 10.

In a comparative example where a plurality of memory portions are electrically connected to have one wiring connection structure, one property of a semiconductor device may be improved, but another property of the semiconductor device may be deteriorated. Particularly, it may be difficult to simultaneously improve performance and productivity of the semiconductor device. Thereby, as a number of the memory portions included in the semiconductor device increases, a relatively poor property may be deteriorated severely. Accordingly, it may be difficult to increase the number of the memory portions included in the semiconductor device.

For example, when a plurality of memory portions are entirely connected to have a word-line connection structure, a wiring structure of a wiring portion that is connected to bit lines may be complicated and performance and productivity of the semiconductor device may be deteriorated. For example, when a plurality of memory portions are entirely connected to have a bit-line connection structure, a connection region may be large and it may be difficult to reduce a size of the semiconductor device. Accordingly, productivity of the semiconductor device may be deteriorated. For example, when a plurality of memory portions are entirely connected to have an integrated connection structure, a memory cell block may be large and relatively large power may be used and it may be difficult reduce a disturbance phenomenon. Thereby, performance of the semiconductor device may be deteriorated. Further, a ratio of a spare memory cell block may be large and there may be a limit to reducing a size of the semiconductor device.

In FIG. 1, it is illustrated as example that each memory portion 300 is bonded so that the upper wiring portion 260 faces the circuit region 100 and each memory portion 300 may have a reversed structure. However, the embodiments are not limited thereto. In some embodiments, at least one memory portion 300 having a normal structure may be included. In the normal structure, the lower wiring portion 270 may face the circuit region 100.

In some embodiments, the first memory portion 300a may be bonded to have the normal structure and the second memory portion 300b may be bonded to have the reversed structure, and/or the third memory portion 300c may be bonded to have the normal structure and the fourth memory portion 300d may be bonded to have the reversed structure. In some embodiments, the first memory portion 300a may be bonded to have the reversed structure and the second memory portion 300b may be bonded to have the normal structure, and/or the third memory portion 300c may be bonded to have the reversed structure and the fourth memory portion 300d may be bonded to have the normal structure. As in the above, when the memory portions 300 of the normal structures and the memory portions 300 of the reversed structures are bonded to each other alternately, two adjacent upper bonding structures 264 of two adjacent upper wiring portions 260 included in two adjacent memory portions 300 may be bonded to each other, or two adjacent lower bonding structures 274 of two lower wiring portions 270 included in two adjacent memory portions 300 may be bonded to each other. Other various modifications are possible.

In the normal structure, a portion that is disposed at an upper portion in a manufacturing process (e.g., a portion that is adjacent to the channel pad 244 or the upper wiring portion 260, or a portion that is opposite to the protruding portion CHP of the channel structure CH or the lower wiring portion 270) may be disposed to away from the circuit region 100 in a final structure. In the reversed structure, the portion that is disposed at the upper portion in the manufacturing process (e.g., the portion that is adjacent to the channel pad 244 or the upper wiring portion 260, or the portion that is opposite to the protruding portion CHP of the channel structure CH or the lower wiring portion 270) may be disposed to be adjacent to the circuit region 100 in a final structure.

The normal structure and the reversed structure may be confirmed or seen from a shape of the channel structure CH, the separation structure 246, the gate contact portions 282, the source contact portions 284, the penetrating plug 290, or the like, and/or a shape of the plurality of gate electrodes 230 or the like in the connection region 204.

For example, in the normal structure, in a case that the channel structure CH, the separation structure 246, the gate contact portion 282, the source contact portion 284, or the penetrating plug 290 has an inclined surface, a width of the channel structure CH, the separation structure 246, the gate contact portion 282, the source contact portion 284, or the penetrating plug 290 may gradually decrease toward the circuit region 100. In the normal structure, lengths of the plurality of gate electrodes 230 in the connection region 204 may sequentially increase toward the circuit region 100 to have a normal stair shape.

For example, in the reversed structure, in a case that the channel structure CH, the separation structure 246, the gate contact portion 282, the source contact portion 284, or the penetrating plug 290 has an inclined surface, a width of the channel structure CH, the separation structure 246, the gate contact portion 282, the source contact portion 284, or the penetrating plug 290 may gradually increase toward the circuit region 100. In the reversed structure, lengths of the plurality of gate electrodes 230 in the connection region 204 may sequentially decrease toward the circuit region 100 to have a reversed stair shape.

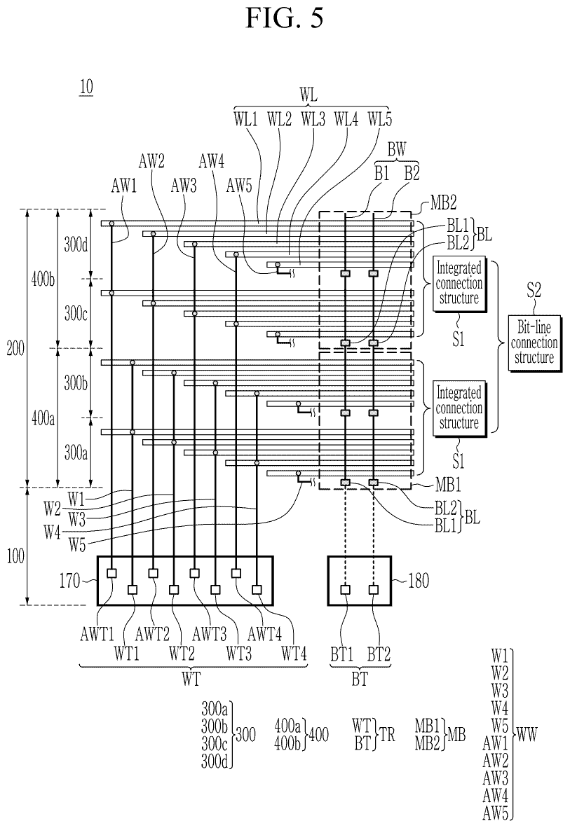

Hereinafter, referring to FIG. 5 to FIG. 10, semiconductor devices according to embodiments will be described in detail. To the extent that an element is not described in detail below, it may be understood that the element is at least similar to a corresponding element that has been described elsewhere within the present disclosure. A portion which is not described in the above will be described in detail.

FIG. 5 conceptually illustrates a wiring connection structure of a semiconductor device according to an embodiment. In FIG. 5, an electrical connection structure between word lines WL and word connection wirings WW and an electrical connection structure between bit lines BL and bit connection wirings BW are illustrated in the same manner as in FIG. 4. In FIG. 5, it is illustrated as example that positions of first to word connection wirings WW electrically connected to fifth word lines WL1, WL2, WL3, WL4, and WL5 in a first memory group 400a and/or a second memory group 400b, but the embodiments are not limited thereto.

Referring to FIG. 5, in an embodiment, a plurality of memory portions 300 that are included in each memory group 400 may be electrically connected to have a first wiring connection structure S1, which is an integrated connection structure, and the plurality of memory groups 400 may be electrically connected to have a second wiring connection structure S2, which is a bit-line connection structure.

In an embodiment, since the plurality of memory portions 300 that are included in each memory group 400 may be electrically connected to have the integrated connection structure, bit connection wirings BW may be shared in first and second memory portions 300a and 300b that are included in a first memory group 400a, and bit connection wirings BW may be shared in third and fourth memory portions 300c and 300d that are included in a second memory group 400b. Since the plurality of memory groups 400 may be electrically connected to have the bit-line connection structure, the bit connection wirings BW may be shared in the first memory group 400a and the second memory group 400b. That is, the plurality of bit connection wirings BW may be shared in the first to fourth memory portions 300a, 300b, 300c, and 300d.

For example, a plurality of first bit lines BL1 (e.g., corresponding bit lines BL) that are included in the first to fourth memory portions 300a, 300b, 300c, and 300d and correspond to each other may be electrically connected to a same wiring (e.g., a first bit connection wiring B1), and/or may be electrically connected to a same bit transistor BT (e.g., a first bit transistor BT1). That is, the plurality of first bit lines BL1 (e.g., corresponding bit lines BL) that are included in the first to fourth memory portions 300a, 300b, 300c, and 300d and correspond to each other may be merged, integrated, or shared, and/or a same signal may be applied to the plurality of first bit lines BL1 (e.g., corresponding bit lines BL) that are included in the first to fourth memory portions 300a, 300b, 300c, and 300d and correspond to each other.

For example, a plurality of second bit lines BL2 (e.g., corresponding bit lines BL) that are included in the first to fourth memory portions 300a, 300b, 300c, and 300d and correspond to each other may be electrically connected to a same wiring (e.g., a second bit connection wiring B2), and/or may be electrically connected to a same bit transistor BT (e.g., a second bit transistor BT2). That is, the plurality of second bit lines BL2 (e.g., corresponding bit lines BL) that are included in the first to fourth memory portions 300a, 300b, 300c, and 300d and correspond to each other may be merged, integrated, or shared, and/or a same signal may be applied to the plurality of second bit lines BL2 (e.g., corresponding bit lines BL) that are included in the first to fourth memory portions 300a, 300b, 300c, and 300d and correspond to each other.

In an embodiment, since the plurality of memory portions 300 that are included in each memory group 400 may be electrically connected to have the integrated connection structure, the word connection wirings WW may be shared in the first and second memory portions 300a and 300b that are included in the first memory group 400a, and the word connection wirings WW may be shared in the third and fourth memory portions 300c and 300d that are included in the second memory group 400b. Since the plurality of memory groups 400 may be electrically connected to have the bit-line connection structure, the word connection wirings WW of the first memory group 400a and the word connection wirings WW of the second memory group 400b may be individually or independently provided not to be electrically connected to each other, or may be electrically connected to different word transistors WT.

That is, the plurality of word connection wirings WW may include word connection wirings WW (e.g., first to fourth word connection wirings W1, W2, W3, and W2) that are shared in one of the plurality of memory groups 400 (e.g., the first and second memory portions 300a and 300b that are included in the first memory group 400a) and word connection wirings WW (e.g., first to fourth additional word connection wirings AW1, AW2, AW3, and AB4) that are shared in another one of the plurality of memory groups 400 (e.g., the third and fourth memory portions 300c and 300d that are included in the second memory group 400b).

For example, a plurality of first word lines WL1 (e.g., corresponding word lines WL) that are included in the first and second memory portions 300a and 300b and correspond to each other may be electrically connected to a same wiring (e.g., the first word connection wiring W1), and/or may be electrically connected to a same word transistors WT (e.g., a first word transistor WT1). That is, the plurality of first word lines WL1 (e.g., corresponding word lines WL) that are included in the first and second memory portions 300a and 300b and correspond to each other may be merged, integrated, or shared, and/or a same signal may be applied to the plurality of first word lines WL1 (e.g., corresponding word lines WL) that are included in the first and second memory portions 300a and 300b and correspond to each other.

A plurality of second word lines WL2 (e.g., corresponding word lines WL) that are included in the first and second memory portions 300a and 300b and correspond to each other may be electrically connected to a same wiring (e.g., the second word connection wiring W2), and/or may be electrically connected to a same word transistors WT (e.g., a second word transistor WT2). That is, the plurality of second word lines WL2 (e.g., corresponding word lines WL) that are included in the first and second memory portions 300a and 300b and correspond to each other may be merged, integrated, or shared, and/or a same signal may be applied to the plurality of second word lines WL2 (e.g., corresponding word lines WL) that are included in the first and second memory portions 300a and 300b and correspond to each other.

A plurality of third word lines WL3 (e.g., corresponding word lines WL) that are included in the first and second memory portions 300a and 300b and correspond to each other may be electrically connected to a same wiring (e.g., the third word connection wiring W3), and/or may be electrically connected to a same word transistors WT (e.g., a third word transistor WT3). That is, the plurality of third word lines WL3 (e.g., corresponding word lines WL) that are included in the first and second memory portions 300a and 300b and correspond to each other may be merged, integrated, or shared, and/or a same signal may be applied to the plurality of third word lines WL3 (e.g., corresponding word lines WL) that are included in the first and second memory portions 300a and 300b and correspond to each other.

A plurality of fourth word lines WL4 (e.g., corresponding word lines WL) that are included in the first and second memory portions 300a and 300b and correspond to each other may be electrically connected to a same wiring (e.g., the fourth word connection wiring W4), and/or may be electrically connected to a same word transistors WT (e.g., a fourth word transistor WT4). That is, the plurality of fourth word lines WL4 (e.g., corresponding word lines WL) that are included in the first and second memory portions 300a and 300b and correspond to each other may be merged, integrated, or shared, and/or a same signal may be applied to the plurality of fourth word lines WL4 (e.g., corresponding word lines WL) that are included in the first and second memory portions 300a and 300b and correspond to each other.

For example, a plurality of first word lines WL1 (e.g., corresponding word lines WL) that are included in the third and fourth memory portions 300c and 300d and correspond to each other may be electrically connected to a same wiring (e.g., the first additional word connection wiring AW1), and/or may be electrically connected to a same word transistors WT (e.g., a first additional word transistor WT1). That is, the plurality of first word lines WL1 (e.g., corresponding word lines WL) that are included in the third and fourth memory portions 300c and 300d and correspond to each other may be merged, integrated, or shared, and/or a same signal may be applied to the plurality of first word lines WL1 (e.g., corresponding word lines WL) that are included in the third and fourth memory portions 300c and 300d and correspond to each other.

A plurality of second word lines WL2 (e.g., corresponding word lines WL) that are included in the third and fourth memory portions 300c and 300d and correspond to each other may be electrically connected to a same wiring (e.g., the second additional word connection wiring AW2), and/or may be electrically connected to a same word transistors WT (e.g., a second additional word transistor WT2). That is, the plurality of second word lines WL2 (e.g., corresponding word lines WL) that are included in the third and fourth memory portions 300c and 300d and correspond to each other may be merged, integrated, or shared, and/or a same signal may be applied to the plurality of second word lines WL2 (e.g., corresponding word lines WL) that are included in the third and fourth memory portions 300c and 300d and correspond to each other.

A plurality of third word lines WL3 (e.g., corresponding word lines WL) that are included in the third and fourth memory portions 300c and 300d and correspond to each other may be electrically connected to a same wiring (e.g., the third additional word connection wiring AW3), and/or may be electrically connected to a same word transistors WT (e.g., a third additional word transistor WT3). That is, the plurality of third word lines WL3 (e.g., corresponding word lines WL) that are included in the third and fourth memory portions 300c and 300d and correspond to each other may be merged, integrated, or shared, and/or a same signal may be applied to the plurality of third word lines WL3 (e.g., corresponding word lines WL) that are included in the third and fourth memory portions 300c and 300d and correspond to each other.

A plurality of fourth word lines WL4 (e.g., corresponding word lines WL) that are included in the third and fourth memory portions 300c and 300d and correspond to each other may be electrically connected to a same wiring (e.g., the fourth additional word connection wiring AW4), and/or may be electrically connected to a same word transistors WT (e.g., a fourth additional word transistor WT4). That is, the plurality of fourth word lines WL4 (e.g., corresponding word lines WL) that are included in the third and fourth memory portions 300c and 300d and correspond to each other may be merged, integrated, or shared, and/or a same signal may be applied to the plurality of fourth word lines WL4 (e.g., corresponding word lines WL) that are included in the third and fourth memory portions 300c and 300d and correspond to each other.

In an embodiment, a plurality of fifth word lines WL5 that are included in the first to fourth memory portions 300a, 300b, 300c, and 300d may not be electrically connected to each other, and the fifth word connection wirings W5 or the fifth additional word connection wirings AW5 that are connected to the plurality of fifth word lines WL5, respectively, which are included in the first to fourth memory portions 300a, 300b, 300c, and 300d may be individually or independently provided not to be electrically connected to each other. However, the embodiments are not limited thereto, and at least two of the plurality of fifth word lines WL5 that are included in the first to fourth memory portions 300a, 300b, 300c, and 300d may be electrically connected to each other.

In an embodiment, a memory cell block MB may be associated with a part of the plurality of memory groups to be associated with one or more memory portions. For example, a memory cell block MB may correspond to at least one memory group, partially correspond to the plurality of memory portions 300 in the memory group, and/or correspond to one or more memory portions of the plurality of memory portions in memory group. In an embodiment, a memory cell block MB may partially correspond to the plurality of memory portions 300, and accordingly correspond to one or more memory portions of the plurality of memory portions 300. For example, the memory cell block MB may correspond to each memory group 400. A first memory cell block MB1 may correspond to the first and second memory portions 300a and 300b, and a second memory cell block MB2 may correspond to the third and fourth memory portions 300c and 300d.

As in the above, in an embodiment, the plurality of memory portions 300 that are included in each memory group 400 may be electrically connected to have the integrated connection structure, and the plurality of memory groups 400 may be electrically connected to have the bit-line connection structure. Thereby, performance and productivity of a semiconductor device 10 may be enhanced together. Particularly, in an embodiment, a wiring structure of an upper wiring portion that is connected to the bit lines BL may be simplified.

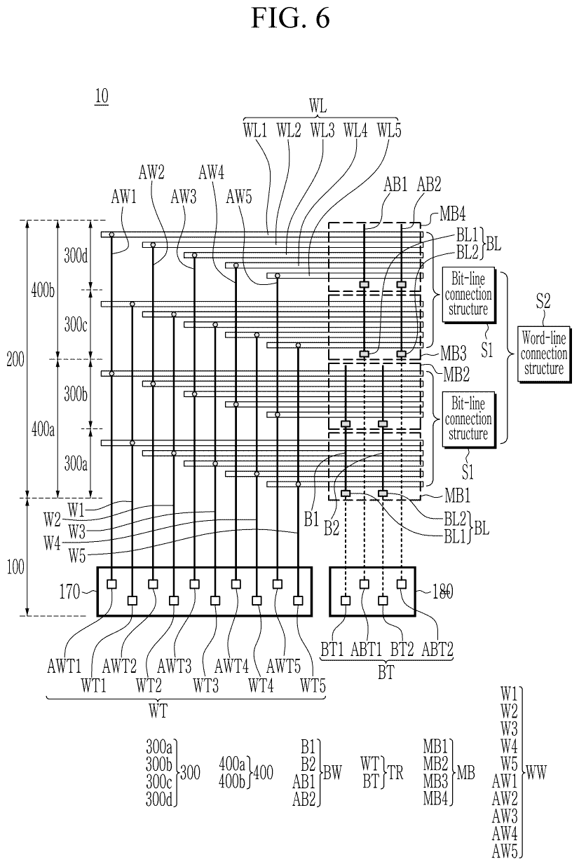

FIG. 6 conceptually illustrates a wiring connection structure of a semiconductor device according to an embodiment. In FIG. 6, an electrical connection structure between word lines WL and word connection wirings WW and an electrical connection structure between bit lines BL and bit connection wirings BW are illustrated in the same manner as in FIG. 4.

Referring to FIG. 6, in an embodiment, a plurality of memory portions 300 that are included in each memory group 400 may be electrically connected to have a first wiring connection structure S1, which is a bit-line connection structure, and the plurality of memory groups 400 may be electrically connected to have a second wiring connection structure S2, which is a word-line connection structure.

In an embodiment, since the plurality of memory portions 300 that are included in each memory group 400 may be electrically connected to have the bit-line connection structure, bit connection wirings BW may be shared in first and second memory portions 300a and 300b that are included in a first memory group 400a, and bit connection wirings BW may be shared in third and fourth memory portions 300c and 300d that are included in a second memory group 400b. Since the plurality of memory groups 400 may be electrically connected to have the word-line connection structure, the bit connection wirings BW of the first memory group 400a and the bit connection wirings BW of the second memory group 400b may be individually or independently provided not to be electrically connected to each other, or may be electrically connected to different bit transistors BT.

That is, the plurality of bit connection wirings BW may include bit connection wirings BW (e.g., first and second bit connection wirings B1 and B2) that are shared in one of the plurality of memory groups 400 (e.g., the first and second memory portions 300a and 300b that are included in the first memory group 400a) and bit connection wirings BW (e.g., first and second additional bit connection wirings AB1 and AB2) that are shared in another one of the plurality of memory groups 400 (e.g., the third and fourth memory portions 300c and 300d that are included in the second memory group 400b). The description of bit lines BL, bit connection wirings BW, and bit transistors BT with reference to FIG. 4 may be applied thereto.

As in the above, the plurality of memory portions 300 that are included in each memory group 400 may be electrically connected to have the bit-line connection structure. Accordingly, in the first memory portion 300a and the second memory portion 300b that are included in the first memory group 400a, word connection wirings WW may be individually or independently provided not to be connected to each other, and/or or may be electrically connected to different word transistors WT. In the third memory portion 300c and the fourth memory portion 300d that are included in the second memory group 400b, word connection wirings WW may be individually or independently provided not to be connected to each other, and/or or may be electrically connected to different word transistors WT.

Since the plurality of memory groups 400 may be electrically connected to have the word-line connection structure, the word connection wirings WW or the first memory group 400a and the word connection wirings WW of the second memory group 400b may be shared. More particularly, in the first memory portion 300a that is included in the first memory group 400a and the third memory portion 300c that is included in the second memory group 400b, the word connection wirings WW (e.g., the first to fifth word connection wirings W1, W2, W3, W4, and W5) may be shared. In the second memory portion 300b that is included in the first memory group 400a and the fourth memory portion 300d that is included in the second memory group 400b, the word connection wirings WW (e.g., the first to fifth additional word connection wirings AW1, AW2, AW3, AW4, and AW5) may be shared. The first to fifth word connection wirings W1, W2, W3, W4, and W5 and the first to fifth additional word connection wirings AW1, AW2, AW3, AW4, and AW5 may be individually or independently provided not to be electrically connected to each other.

For example, the plurality of first, second, third, fourth, or fifth word lines WL1, WL2, WL3, WL4, or WL5 (e.g., corresponding word lines WL) that are included in the first and third memory portions 300a and 300c and correspond to each other may be electrically connected to a same wiring (e.g., the first, second, third, fourth, or fifth word connection wiring W1, W2, W3, W4, or W5), and/or may be electrically connected to a same word transistors WT (e.g., the first, second, third, fourth, or fifth word transistor WT1, WT2, WT3, WT4, or WT5).

That is, the plurality of first, second, third, fourth, or fifth word lines WL1, WL2, WL3, WL4, or WL5 (e.g., corresponding word lines WL) that are included in the first and third memory portions 300a and 300c and correspond to each other may be merged, integrated, or shared, and/or a same signal may be applied to the plurality of first, second, third, fourth, or fifth word lines WL1, WL2, WL3, WL4, or WL5 (e.g., corresponding word lines WL) that are included in the first and third memory portions 300a and 300c and correspond to each other.

For example, the plurality of first, second, third, fourth, or fifth word lines WL1, WL2, WL3, WL4, or WL5 (e.g., corresponding word lines WL) that are included in the second and fourth memory portions 300b and 300d and correspond to each other may be electrically connected to a same wiring (e.g., the first, second, third, fourth, or fifth additional word connection wiring AW1, AW2, AW3, AW4, or AW5), and/or may be electrically connected to a same word transistors WT (e.g., a first, second, third, fourth, or fifth additional word transistor AWT1, AWT2, AWT3, AWT4, or AWT5).

That is, the plurality of first, second, third, fourth, or fifth word lines WL1, WL2, WL3, WL4, or WL5 (e.g., corresponding word lines WL) that are included in the second and fourth memory portions 300b and 300d and correspond to each other may be merged, integrated, or shared, and/or a same signal may be applied to the plurality of first, second, third, fourth, or fifth word lines WL1, WL2, WL3, WL4, or WL5 (e.g., corresponding word lines WL) that are included in the second and fourth memory portions 300b and 300d and correspond to each other.

In an embodiment, a memory cell block MB may be associated with a part of the plurality of memory groups to be associated with one or more memory portions. For example, the memory cell block MB may correspond to each memory portion 300. That is, a first memory cell block MB1 may correspond to the first memory portion 300a, a second memory cell block MB2 may correspond to the second memory portion 300b, a third memory cell block MB3 may correspond to the third memory portion 300c, and a fourth memory cell block MB4 may correspond to the fourth memory portion 300d.

In FIG. 6 and the description, it is illustrated and described as an example that at least two of the plurality of fifth word lines WL5 that are included in the plurality of memory portions 300 may be electrically connected to each other. However, the embodiments are not limited thereto, and the plurality of fifth word lines WL5 that are included in the plurality of memory portions 300 may not be electrically connected to each other, as illustrated in FIG. 4 or in FIG. 5.

As in the above, in an embodiment, the plurality of memory portions 300 that are included in each memory group 400 may be electrically connected to have the bit-line connection structure, and the plurality of memory groups 400 may be electrically connected to have the word-line connection structure. Thereby, performance and productivity of a semiconductor device 10 may be enhanced. Particularly, in an embodiment, a size of the memory cell block MB may be reduced more and the performance of the semiconductor device may be enhanced more.

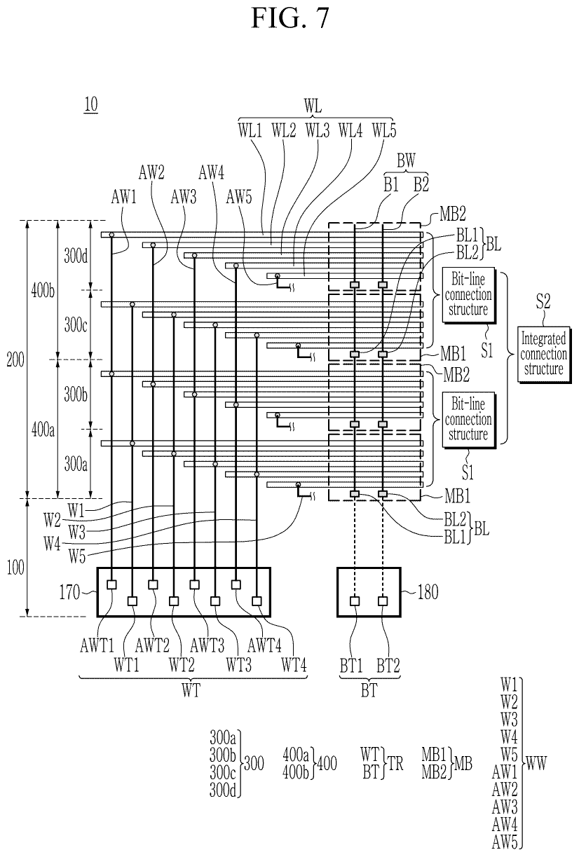

FIG. 7 conceptually illustrates a wiring connection structure of a semiconductor device according to an embodiment. In FIG. 7, an electrical connection structure between word lines WL and word connection wirings WW and an electrical connection structure between bit lines BL and bit connection wirings BW are illustrated in the same manner as in FIG. 4.

Referring to FIG. 7, in an embodiment, a plurality of memory portions 300 that are included in each memory group 400 may be electrically connected to have a first wiring connection structure S1, which is a bit-line connection structure, and the plurality of memory groups 400 may be electrically connected to have a second wiring connection structure S2, which is an integrated connection structure.

In an embodiment, the plurality of memory portions 300 that are included in each memory group 400 may be electrically connected to have the bit-line connection structure. That is, bit connection wirings BW may be shared in the first and second memory portions 300a and 300b that are included in the first memory group 400a, and bit connection wirings BW may be shared in the third and fourth memory portions 300c and 300d that are included in the second memory group 400b. Since the plurality of memory groups 400 may be electrically connected to have the integrated connection structure, the bit connection wirings BW may be shared in the first memory group 400a and the second memory group 400b. That is, the plurality of bit connection wirings BW may be shared in the first to fourth memory portions 300a, 300b, 300c, and 300d. The description of bit lines BL, bit connection wirings BW, and bit transistors BT with reference to FIG. 5 may be applied thereto.

As in the above, the plurality of memory portions 300 that are included in each memory group 400 may be electrically connected to have the bit-line connection structure. Accordingly, in the first memory portion 300a and the second memory portion 300b that are included in the first memory group 400a, word connection wirings WW may be individually or independently provided not to be connected to each other, and/or or may be electrically connected to different word transistors WT. In the third memory portion 300c and the second memory portion 300d that are included in the second memory group 400b, word connection wirings WW may be individually or independently provided not to be connected to each other, and/or or may be electrically connected to different word transistors WT. Since the plurality of memory groups 400 may be electrically connected to have the integrated connection structure, the word connection wirings WW of the first memory group 400a and the word connection wirings WW of the second memory group 400b may be shared. Unless otherwise described, the description of word lines WL, word connection wirings WW, and word transistors WT with reference to FIG. 6 may be applied thereto.

In an embodiment, a memory cell block MB may be associated with a part of the plurality of memory groups to be associated with one or more memory portions. For example, a first memory cell block MB1 may correspond to the first memory portion 300a and the third memory portion 300c, and a second memory cell block MB2 may correspond to the second memory portion 300b and the fourth memory portion 300d. In an embodiment, a plurality of fifth word lines WL5 that are included in the first to fourth memory portions 300a, 300b, 300c, and 300d may not be electrically connected to each other. Fifth word connection wirings W5 or fifth additional word connection wirings AW5 that are connected to a plurality of fifth word lines WL5, respectively, which are included in the first to fourth memory portions 300a, 300b, 300c, and 300d may be individually or independently provided not to be electrically connected to each other. However, the embodiments are not limited thereto, and at least two of the plurality of fifth word lines WL5 that are included in the first to fourth memory portions 300a, 300b, 300c, and 300d may be electrically connected to each other.

As in the above, in an embodiment, the plurality of memory portions 300 that are included in each memory group 400 may be electrically connected to have the bit-line connection structure, and the plurality of memory groups 400 may be electrically connected to have the integrated connection structure. Thereby, performance and productivity of a semiconductor device 10 may be enhanced together. Particularly, in an embodiment, a wiring structure of an upper wiring portion that is connected to bit lines BL may be simplified.

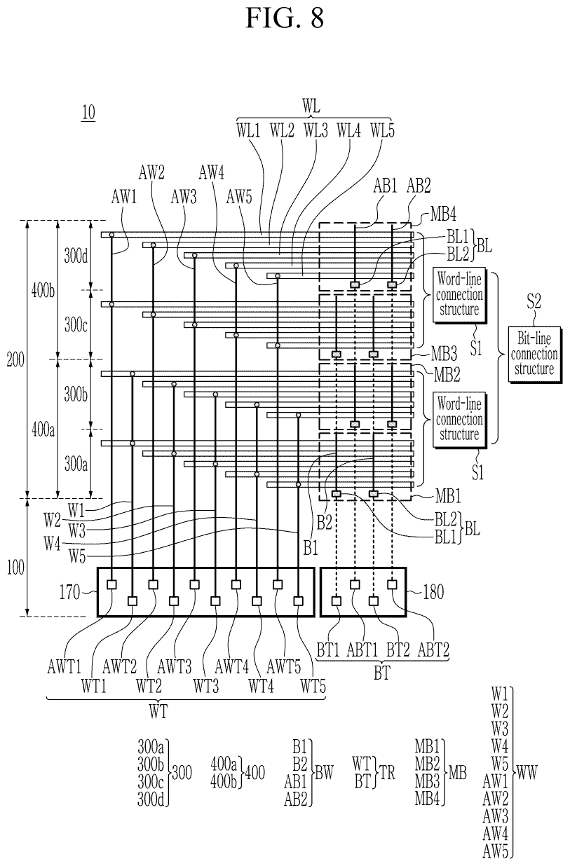

FIG. 8 conceptually illustrates a wiring connection structure of a semiconductor device according to an embodiment. In FIG. 8, an electrical connection structure between word lines WL and word connection wirings WW and an electrical connection structure between bit lines BL and bit connection wirings BW are illustrated in the same manner as in FIG. 4.

Referring to FIG. 8, in an embodiment, a plurality of memory portions 300 that are included in each memory group 400 may be electrically connected to have a first wiring connection structure S1, which is a bit-line connection structure, and the plurality of memory groups 400 may be electrically connected to have a second wiring connection structure S2, which is an integrated connection structure.

In an embodiment, since the plurality of memory portions 300 that are included in each memory group 400 may be electrically connected to have the word-line connection structure, word connection wirings WW may be shared in first and second memory portions 300a and 300b that are included in a first memory group 400a, and word connection wirings WW may be shared in the third and fourth memory portions 300c and 300d that are included in a second memory group 400b. Since the plurality of memory groups 400 may be electrically connected to have the bit-line connection structure, the word connection wirings WW of the first memory group 400a and the word connection wirings WW of the second memory group 400b may be individually or independently provided not to be electrically connected to each other, or may be electrically connected to different word transistors WT. The description of word lines WL, word connection wirings WW, and word transistors WT with reference to FIG. 5 may be applied thereto.

As in the above, the plurality of memory portions 300 that are included in each memory group 400 may be electrically connected to have the word-line connection structure. Accordingly, in the first memory portion 300a and the second memory portion 300b that are included in the first memory group 400a, bit connection wirings BW may be individually or independently provided not to be connected to each other, and/or may be electrically connected to different bit transistors BT. In the third memory portion 300c and the fourth memory portion 300d that are included in the second memory group 400b, bit connection wirings BW may be individually or independently provided not to be connected to each other, and/or may be electrically connected to different bit transistors BT.

Since the plurality of memory groups 400 may be electrically connected to have the bit-line connection structure, the bit connection wirings BW of the first memory group 400a and the bit connection wirings BW of the second memory group 400b may be shared. More particularly, in the first memory portion 300a that is included in the first memory group 400a and the third memory portion 300c that is included in the second memory group 400b, bit connection wirings BW (e.g., first and second bit connection wirings B1 and B2) may be shared. In the second memory portion 300b that is included in the first memory group 400a and the fourth memory portion 300d that is included in the second memory group 400b, bit connection wirings BW (e.g., first and second additional bit connection wirings AB1 and AB2) may be shared. The first and second bit connection wirings B1 and B2 and the first and second additional bit connection wirings AB1 and AB2 may be individually or independently provided not to be electrically connected to each other.

For example, a plurality of first or second bit lines BL1 or BL2 (e.g., corresponding bit lines BL) that are included in the first and third memory portions 300a and 300c and correspond to each other may be electrically connected to a same wiring (e.g., the first or second bit connection wiring B1 or B2), and/or may be electrically connected to a same bit transistor BT (e.g., a first or second bit transistor BT1 or BT2).

That is, the plurality of first or second bit lines BL1 or BL2 (e.g., corresponding bit lines BL) that are included in the first and third memory portions 300a and 300c and correspond to each other may be merged, integrated, or shared, and/or a same signal may be applied to the plurality of first or second bit lines BL1 or BL2 (e.g., corresponding bit lines BL) that are included in the first and third memory portions 300a and 300c and correspond to each other.

For example, a plurality of first or second bit lines BL1 or BL2 (e.g., corresponding bit lines BL) that are included in the second and fourth memory portions 300b and 300d and correspond to each other may be electrically connected to a same wiring (e.g., the first or second additional bit connection wiring AB1 or AB2), and/or may be electrically connected to a same bit transistor BT (e.g., a first or second additional bit transistor ABT1 or ABT2).

That is, the plurality of first or second bit lines BL1 or BL2 (e.g., corresponding bit lines BL) that are included in the second and fourth memory portions 300b and 300d and correspond to each other may be merged, integrated, or shared, and/or a same signal may be applied to the plurality of first or second bit lines BL1 or BL2 (e.g., corresponding bit lines BL) that are included in the second and fourth memory portions 300b and 300d and correspond to each other.

In an embodiment, a memory cell block MB may be associated with a part of the plurality of memory groups to be associated with one or more memory portions. For example, the memory cell block MB may correspond to each memory portion 300. That is, a first memory cell block MB1 may correspond to the first memory portion 300a, a second memory cell block MB2 may correspond to the second memory portion 300b, a third memory cell block MB3 may correspond to the third memory portion 300c, and a fourth memory cell block MB4 may correspond to the fourth memory portion 300d.

In FIG. 8 and the description, it is illustrated and described as an example that at least two of a plurality of fifth word lines WL5 that are included in the plurality of memory portions 300 may be electrically connected to each other. However, the embodiments are not limited thereto, and the plurality of fifth word lines WL5 that are included in the plurality of memory portions 300 may not be electrically connected to each other, as illustrated in FIG. 4 or in FIG. 5.

As in the above, in an embodiment, the plurality of memory portions 300 that are included in each memory group 400 may be electrically connected to have the word-line connection structure, and the plurality of memory groups 400 may be electrically connected to have the bit-line connection structure. Thereby, performance and productivity of a semiconductor device 10 may be enhanced. Particularly, in an embodiment, a size of the memory cell block MB may be reduced more and the performance of the semiconductor device may be enhanced more.

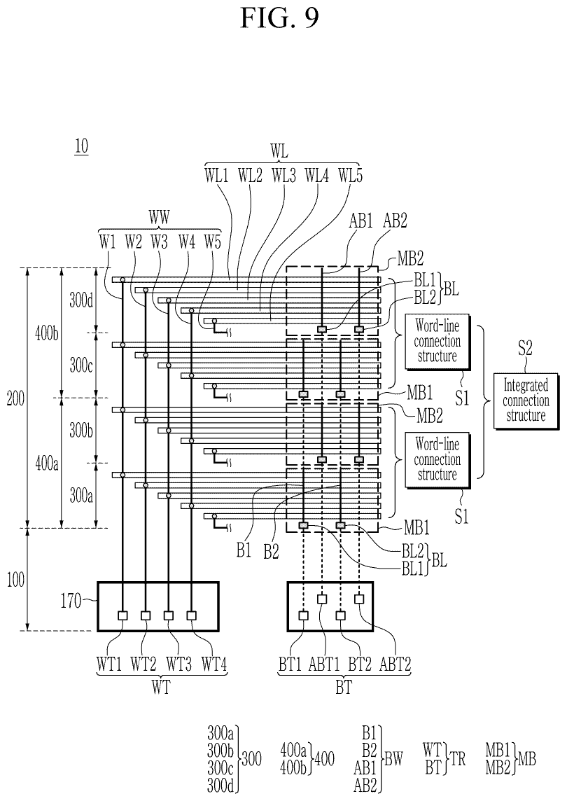

FIG. 9 conceptually illustrates a wiring connection structure of a semiconductor device according to an embodiment. In FIG. 9, an electrical connection structure between word lines WL and word connection wirings WW and an electrical connection structure between bit lines BL and bit connection wirings BW are illustrated in the same manner as in FIG. 4.

Referring to FIG. 9, in an embodiment, a plurality of memory portions 300 that are included in each memory group 400 may be electrically connected to have a first wiring connection structure S1, which is a word-line connection structure, and the plurality of memory groups 400 may be electrically connected to have a second wiring connection structure S2, which is an integrated connection structure.

In an embodiment, since the plurality of memory portions 300 that are included in each memory group 400 may be electrically connected to have the word-line connection structure, word connection wirings WW may be shared in first and second memory portions 300a and 300b that are included in a first memory group 400a, and word connection wirings WW may be shared in third and fourth memory portions 300c and 300d that are included in a second memory group 400b. Since the plurality of memory groups 400 may be electrically connected to have the integrated connection structure, the word connection wirings WW may be shared in the first memory group 400a and the second memory group 400b. That is, the plurality of word connection wirings WW may be shared in the first to fourth memory portions 300a, 300b, 300c, and 300d. The description of word lines WL, word connection wirings WW, and word transistors WT with reference to FIG. 4 may be applied thereto.

As in the above, the plurality of memory portions 300 that are included in each memory group 400 may be electrically connected to have the word-line connection structure. Accordingly, in the first memory portion 300a and the second memory portion 300b that are included in the first memory group 400a, bit connection wirings BW may be individually or independently provided not to be connected to each other, and/or may be electrically connected to different bit transistors BT. In the third memory portion 300c and the fourth memory portion 300d that are included in the second memory group 400b, bit connection wirings BW may be individually or independently provided not to be connected to each other, and/or may be electrically connected to different bit transistors BT.

Since the plurality of memory groups 400 may be electrically connected to have the integrated connection structure, the bit connection wirings BW of the first memory group 400a and the bit connection wirings BW of the second memory group 400b may be shared. More particularly, in the first memory portion 300a that is included in the first memory group 400a and the third memory portion 300c that is included in the second memory group 400b, the bit connection wirings BW (e.g., first and second bit connection wirings B1 and B2) may be shared. In the second memory portion 300b that is included in the first memory group 400a and the fourth memory portion 300d that is included in the second memory group 400b, the bit connection wirings BW (e.g., first and second additional bit connection wirings AB1 and AB2) may be shared. The first and second bit connection wirings B1 and B2 and the first and second additional bit connection wirings AB1 and AB2 may be individually or independently provided not to be electrically connected to each other. The description of bit lines BL, bit connection wirings BW, and bit transistor BT with reference to FIG. 8 may be applied thereto.

In an embodiment, a memory cell block MB may be associated with a part of the plurality of memory groups to be associated with one or more memory portions. For example, a first memory cell block MB1 may correspond to the first memory portion 300a and the third memory portion 300c, and a second memory cell block MB2 may correspond to the second memory portion 300b and the fourth memory portion 300d.

In an embodiment, a plurality of fifth word lines WL5 that are included in the first to fourth memory portions 300a, 300b, 300c, and 300d may not be electrically connected to each other, and fifth word connection wirings W5 that are connected to the plurality of fifth word lines WL5, respectively, which are included in the first to fourth memory portions 300a, 300b, 300c, and 300d may be individually or independently provided not to be electrically connected to each other. However, the embodiments are not limited thereto, and at least two of the plurality of fifth word lines WL5 that are included in the first to fourth memory portions 300a, 300b, 300c, and 300d may be electrically connected to each other.

As in the above, in an embodiment, the plurality of memory portions 300 that are included in each memory group 400 may be electrically connected to have the word-line connection structure, and the plurality of memory groups 400 may be electrically connected to have the integrated connection structure. Thereby, performance and productivity of a semiconductor device 10 may be enhanced together. Particularly, in an embodiment, by effectively reducing lengths of gate electrodes in a connection region and a size of the connection region, performance of the semiconductor device 10 may be effectively enhanced and a size of the semiconductor device 10 may be effectively reduced.

FIG. 10 schematically illustrates a wiring connection structure of a semiconductor device according to an embodiment.

Referring to FIG. 10, in an embodiment, a plurality of memory sets 500, each including a plurality of memory groups 400, may be included.

For a clear understanding and simple illustration, it is illustrated and described as an example that the plurality of memory sets 500 include a first memory set 500a and a second memory set 500b, the first memory set 500a includes a first memory group 400a and a second memory group 400b sequentially bonded on the circuit region 100, and the second memory set 500b includes a first memory group 400a and a second memory group 400b sequentially bonded on the first memory set 500a. It is illustrated and described as an example that the first memory group 400a may include first and second memory portions 300a and 300b, and the second memory group 400b may include third and fourth memory portions 300c and 300d. However, the embodiments are not limited thereto, and three or more memory sets 500 may be included, each memory set 500 may include three or more memory groups 400, and/or each memory group 400 may include three or more memory portions 300.

In an embodiment, the plurality of memory portions 300 that are included in each memory group 400 may be electrically connected to have a first wiring connection structure S1, and the plurality of memory groups 400 may be electrically connected to have a second wiring connection structure S2 different from the first wiring connection structure S1. The plurality of memory sets 500 may have a third wiring connection structure S3 different from the second wiring connection structure S2. For example, the plurality of memory sets 500 may have the third wiring connection structure S3 different from each of the first wiring connection structure S1 and the second wiring connection structure S2. However, the embodiments are not limited thereto, and the third wiring connection structure S3 may be same as the first wiring connection structure S1.

In an embodiment, the first wiring connection structure S1 may be one of a word-line connection structure, a bit-line connection structure, and an integrated connection structure. The second wiring connection structure S2 may be another one of the word-line connection structure, the bit-line connection structure, and the integrated connection structure. The third wiring connection structure S3 may be yet another one of the word-line connection structure, the bit-line connection structure, and the integrated connection structure.

For example, as illustrated in FIG. 10, the first wiring connection structure S1 may be the integrated connection structure, the second wiring connection structure S2 may be the word-line connection structure, and the third wiring connection structure S3 may be the bit-line connection structure.

In some embodiments, the first wiring connection structure S1 may be the integrated connection structure, the second wiring connection structure S2 may be the bit-line connection structure, and the third wiring connection structure S3 may be the word-line connection structure.

In some embodiments, the first wiring connection structure S1 may be the bit-line connection structure, the second wiring connection structure S2 may be the word-line connection structure, and the third wiring connection structure S3 may be the integrated connection structure

In some embodiments, the first wiring connection structure S1 may be the bit-line connection structure, the second wiring connection structure S2 may be the integrated connection structure, and the third wiring connection structure S3 may be the word-line connection structure

In some embodiments, the first wiring connection structure S1 may be the word-line connection structure, and the second wiring connection structure S2 may be the bit-line connection structure, and the third wiring connection structure S3 may be the integrated connection structure

In some embodiments, the first wiring connection structure S1 may be the word-line connection structure, and the second wiring connection structure S2 may be the integrated connection structure, and the third wiring connection structure S3 may be the bit-line connection structure

In the description, it is described as an example that a primary connection, a secondary connection, and a tertiary connection are included, but the embodiments are not limited thereto. In this instance, the primary connection connects the plurality of memory portions 300, the secondary connection connects the plurality of memory groups 400, and the tertiary connection connects the plurality of memory sets 500. The plurality of memory portions 300 may be electrically connected to each other by a multi-connection structure that includes four or more connection structures. In this instance, a wiring connection structure of the primary connection may be different from a wiring connection structure of the secondary connection, the wiring connection structure of the secondary connection may be different from a wiring connection structure of the tertiary connection, and the wiring connection structure of the tertiary connection may be different from a wiring connection structure of a quaternary connection. The above relationship may be repeatedly applied to a plurality of connections.

An example of an electronic system including a semiconductor device will be described in detail below.

FIG. 11 schematically illustrates an electronic system including a semiconductor device according to an embodiment.

Referring to FIG. 11, an electronic system 1000 according to an embodiment may include a semiconductor device 1100 and a controller 1200 that is electrically connected to the semiconductor device 1100. The electronic system 1000 may be a storage device that includes one or a plurality of semiconductor devices 1100 or an electronic device that includes the storage device. For example, the electronic system 1000 may be a solid-state drive (SSD) device, a universal serial bus (USB), a computing system, a medical device, or a communication device that includes one or a plurality of semiconductor devices 1100.

The semiconductor device 1100 may be a non-volatile memory device, and for example, may be a NAND flash memory device described with reference to FIG. 1 to FIG. 10. The semiconductor device 1100 may include a first structure 1100F and a second structure 1100S that is disposed on the first structure 1100F. The first structure 1100F may be a peripheral circuit structure that includes a decoder circuit 1110, a page buffer 1120, and a logic circuit 1130. The second structure 1100S may be a memory cell structure that includes a bit line BL, a common source line CSL, a word line WL, first and second gate upper lines UL1 and UL2, first and second gate lower lines LL1 and LL2, and a memory cell string CSTR between the bit line BL and the common source line CSL. In an embodiment, the second structure 1100S may be included in plural. For simple illustration, in FIG. 11 and FIG. 13, one second structure 1100S is illustrated.

In the second structure 1100S, each of memory cell strings CSTR may include lower transistors LT1 and LT2 that are adjacent to the common source line CSL, upper transistors UT1 and UT2 that are adjacent to the bit line BL, and a plurality of memory cell transistors MCT between the lower transistors LT1 and LT2 and the upper transistors UT1 and UT2. A number of the lower transistors LT1 and LT2 and a number of the upper transistors UT1 and UT2 may be variously modified according to an embodiment.

In an embodiment, the lower transistor LT1 or LT2 may include a ground selection transistor, and the upper transistor UT1 or UT2 may include a string selection transistor. The first and second gate lower lines LL1 and LL2 may be gate electrodes of the lower transistors LT1 and LT2, respectively. The word line WL may be a gate electrode of the memory cell transistor MCT, and the gate upper lines UL1 and UL2 may be gate electrodes of the upper transistors UT1 and UT2, respectively.

The common source line CSL, the first and second gate lower lines LL1 and LL2, the word line WL, and the first and second gate upper lines UL1 and UL2 may be electrically connected to the decoder circuit 1110 through a first connection wiring 1115 that extends to the second structure 1100S within the first structure 1100F. The bit line BL may be electrically connected to the page buffer 1120 through a second connection wiring 1125 that extends to the second structure 1100S within the first structure 1100F.

In the first structure 1100F, the decoder circuit 1110 and the page buffer 1120 may execute a control operation for at least one memory cell transistor selected from the plurality of memory cell transistors MCT. The decoder circuit 1110 and the page buffer 1120 may be controlled by the logic circuit 1130. The semiconductor device 1100 may communicate with the controller 1200 through an input/output pad 1101 that is electrically connected to the logic circuit 1130. The input/output pad 1101 may be electrically connected to the logic circuit 1130 through an input/output connection wiring 1135 that extends to the second structure 1100S within the first structure 1100F.

The controller 1200 may include a processor 1210, a NAND controller 1220, and a host interface 1230. In some embodiments, the electronic system 1000 may include a plurality of semiconductor devices 1100, and in this case, the controller 1200 may control the plurality of semiconductor devices 1100.

The processor 1210 may control an overall operation of the electronic system 1000 including the controller 1200. The processor 1210 may operate according to predetermined firmware, and may access the semiconductor device 1100 by controlling the NAND controller 1220. The NAND controller 1220 may include a NAND interface 1221 that processes communication with the semiconductor device 1100. A control command for controlling the semiconductor device 1100, data to be written in the memory cell transistor MCT of the semiconductor device 1100, and data to be read from the memory cell transistor MCT of the semiconductor device 1100, or the like may be transmitted through the NAND interface 1221. The host interface 1230 may provide a communication function between the electronic system 1000 and an external host. When a control command is received from the external host through the host interface 1230, the processor 1210 may control the semiconductor device 1100 in response to the control command.

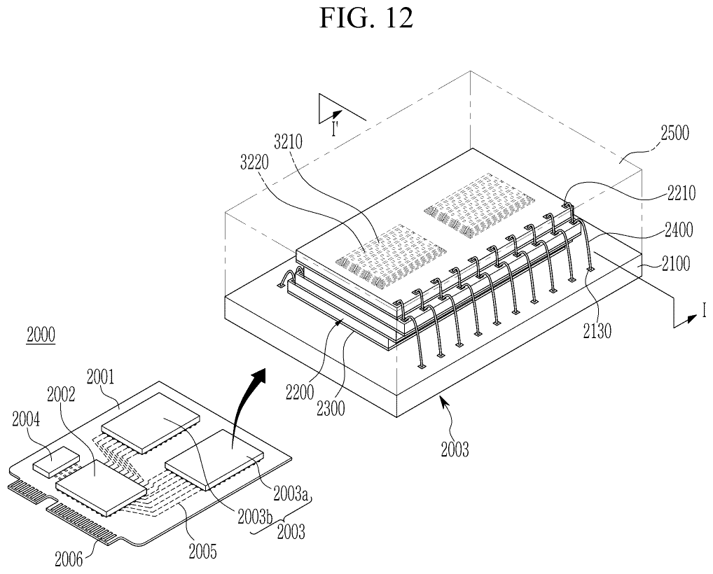

FIG. 12 is a perspective view that schematically illustrates an electronic system including a semiconductor device according to an embodiment.

Referring to FIG. 12, an electronic system 2000 according to an embodiment may include a main substrate 2001, a controller 2002 that is mounted on the main substrate 2001, one or more semiconductor packages 2003, and a DRAM 2004. The semiconductor package 2003 and the DRAM 2004 may be connected to the controller 2002 through a wiring pattern 2005 that is provided on the main substrate 2001.

The main substrate 2001 may include a connector 2006 that includes a plurality of pins coupled to the external host. A number and an arrangement of the plurality of pins in the connector 2006 may vary depending on a communication interface between the electronic system 2000 and the external host. In an embodiment, the electronic system 2000 may communicate with the external host according to any one of interfaces such as a universal serial bus (USB), a peripheral component interconnect express (PCI-Express), a serial advanced technology attachment (SATA), or an M-Phy for a universal flash storage (UFS). In an embodiment, the electronic system 2000 may operate by power that is supplied from the external host through the connector 2006. The electronic system 2000 may further include a power management integrated circuit (PMIC) that distributes the power supplied from the external host to the controller 2002 and the semiconductor package 2003.

The controller 2002 may write data in the semiconductor package 2003 or may read data from the semiconductor package 2003, and may improve an operating speed of the electronic system 2000.

The DRAM 2004 may be a buffer memory for mitigating or buffering a speed difference between the semiconductor package 2003, which is a data storage space, and the external host. The DRAM 2004 that is included in the electronic system 2000 may also be a kind of cache memory, and may also provide a space for temporarily storing data in a control operation for the semiconductor package 2003. When the electronic system 2000 includes the DRAM 2004, the controller 2002 may further include a DRAM controller for controlling the DRAM 2004 in addition to the NAND controller for controlling the semiconductor package 2003.

The semiconductor package 2003 may include first and second semiconductor packages 2003a and 2003b that are spaced apart from each other. Each of the first and second semiconductor packages 2003a and 2003b may be a semiconductor package that includes a plurality of semiconductor chips 2200. Each of the first and second semiconductor packages 2003a and 2003b may include a package substrate 2100, the semiconductor chip 2200 that is disposed on the package substrate 2100, an adhesive layer 2300 at a lower surface of each semiconductor chip 2200, a connection structure 2400 that electrically connects the semiconductor chip 2200 and the package substrate 2100, and a molding layer 2500 that covers the semiconductor chip 2200 and the connection structure 2400 on the package substrate 2100.

The package substrate 2100 may be a printed circuit board that includes a package upper pad 2130. Each semiconductor chip 2200 may include an input/output pad 2210. The input/output pad 2210 may correspond to an input/output pad 1101 of FIG. 11. Each semiconductor chip 2200 may include a gate stacking structure 4210 and a channel structure 4220. The semiconductor chip 2200 may include a semiconductor device described with reference to FIG. 1 to FIG. 10.

In an embodiment, the connection structure 2400 may be a bonding wiring that electrically connects the input/output pad 2210 and the package upper pad 2130. Accordingly, in each of the first and second semiconductor packages 2003a and 2003b, the semiconductor chips 2200 may be electrically connected to each other using a bonding wiring type, and the semiconductor chip 2200 may be electrically connected to the package upper pad 2130 of the package substrate 2100. According to an embodiment, in each of the first and second semiconductor packages 2003a and 2003b, the semiconductor chips 2200 may be electrically connected to each other by a connection structure that includes a through silicon via (TSV) instead of the connection structure 2400 of the bonding wiring type.

In an embodiment, the controller 2002 and the semiconductor chip 2200 may be included in one package. For example, the controller 2002 and the semiconductor chip 2200 may be mounted on a separate interposer substrate that is different from the main substrate 2001, and the controller 2002 and the semiconductor chip 2200 may be connected to each other by a wiring of the interposer substrate.

FIG. 13 is a cross-sectional view that schematically illustrates a semiconductor package according to an embodiment. FIG. 13 respectively illustrates an embodiment of the semiconductor package 2003 of FIG. 12, and conceptually illustrates a region obtained by cutting the semiconductor package 2003 of FIG. 12 along a line I-I′.

Referring to FIG. 13, in the semiconductor package 2003, the package substrate 2100 may be a printed circuit board. The package substrate 2100 may include a package substrate body portion 2120, a package upper pad 2130 at an upper surface of the package substrate body portion 2120, a package lower pad 2125 disposed at a lower surface of the package substrate body portion 2120 or exposed through the lower surface of the package substrate body portion 2120, and an internal wiring 2135 electrically connecting the package upper pad 2130 and the package lower pad 2125 inside the package substrate body portion 2120. The package upper pad 2130 may be electrically connected to the connection structure 2400. The package lower pad 2125 may be connected to the wiring pattern 2005 (refer to FIG. 12) of the main substrate 2001 (refer to FIG. 12) of the electronic system 2000 through a conductive connection portion 2800.

In a semiconductor package 2003, each semiconductor chip 2200 may include a semiconductor substrate 4010, a first structure 4100 on the semiconductor substrate 4010, and a second structure 4200 disposed on the first structure 4100 and bonded to the first structure 4100 by a wafer bonding type.

The first structure 4100 may include a peripheral circuit region including a peripheral wiring 4110 and a first bonding structure 4150. The second structure 4200 may include a common source line 4205, a gate stacking structure 4210 between the common source line 4205 and the first structure 4100, a channel structure 4220 and a separation structure 4230 penetrating the gate stacking structure 4210, and a second bonding structure 4250 electrically connected to the channel structure 4220 and a word line WL (refer to FIG. 11) of the gate stacking structure 4210. For example, the second bonding structure 4250 may be electrically connected to the channel structure 4220 and the word line WL through a bit line 4240 electrically connected to the channel structure 4220 and a gate connection wiring electrically connected to the word line WL. The first bonding structure 4150 of the first structure 4100 and the second bonding structure 4250 of the second structure 4200 may be in contact with and bonded to each other. For example, portions of the first bonding structure 4150 and the second bonding structure 4250 where the first bonding structure 4150 and the second bonding structure 4250 are bonded may include copper (Cu).

In an embodiment, in the memory chip 2200 or a semiconductor device, a plurality of memory portions that are included in each memory group may be electrically connected to have a first wiring connection structure, a plurality of memory groups may be electrically connected to have a second wiring connection structure different from the first wiring connection structure, thereby enhancing performance and productivity together.

Each of the semiconductor chips 2200 may further include an input/output pad 2210 and an input/output connection wiring 4265 at a lower portion of the input/output pad 2210. The input/output connection wiring 4265 may be electrically connected to a part of the second bonding structure 4250.

In an embodiment, in the semiconductor package 2003, the plurality of semiconductor chips 2200 may be electrically connected to each other by the connection structure 2400 having a bonding wiring type. In some embodiments, the plurality of semiconductor chips 2200 or a plurality of portions constituting the plurality of semiconductor chips 2200 may be electrically connected by a connection structure including a through silicon via (TSV).

While some examples have been described in connection with what is presently considered to be some practical embodiments, it is to be understood that the disclosure is not limited to the disclosed embodiments, and that that the disclosure is intended to cover various modifications and equivalent arrangements included within the spirit and scope of the appended claims.

What is claimed is:

1. A semiconductor device, comprising:
a circuit region; and
a cell region stacked on the circuit region,
wherein the cell region comprises a plurality of memory groups,
wherein each of the plurality of memory groups comprises a plurality of memory portions,
wherein a first plurality of memory portions in a first memory group from the plurality of memory groups are connected to through a first wiring connection, and
wherein the first memory group among the plurality of memory groups is connected to a second memory group among the plurality of memory groups through a second wiring connection different from the first wiring connection.

2. The semiconductor device of claim 1, wherein the first plurality of memory portions comprises a first plurality of driving lines,
wherein the first plurality of driving lines comprise a first plurality of word lines and a first plurality of bit lines, wherein the first plurality of bit lines extend in a direction intersecting the first plurality of word lines,
wherein the first wiring connection is one of:
a word-line connection in which corresponding word lines of the first plurality of word lines are connected,
a bit-line connection in which corresponding bit lines of the first plurality of bit lines are connected, and
an integrated connection in which the corresponding word lines are connected and the corresponding bit lines are connected, and
wherein the second wiring connection is another connection from the word-line connection, the bit-line connection, and the integrated connection, that is different than the first wiring connection.

3. The semiconductor device of claim 2, wherein corresponding driving lines of the first plurality of driving lines in the first plurality of memory portions are connected to a same wiring or are connected to a same transistor using the first wiring connection, and
wherein corresponding driving lines in the plurality of memory groups are connected to a same wiring or are connected to a same transistor by the second wiring connection.

4. The semiconductor device of claim 2, wherein each of the first plurality of memory portions comprises:
a gate stack that comprises a plurality of gate electrodes, the plurality of gate electrodes being spaced apart from each other while interposing an interlayer insulation layer and forming the first plurality of word lines;
a plurality of channels that pass through or penetrate the gate stack and are connected to the first plurality of bit lines;
an upper wiring portion disposed at an upper portion of the gate stack and a lower wiring portion disposed at a lower portion of the gate stack; and
a penetrating plug that passes through the gate stack or is disposed outside the gate stack, the penetrating plug electrically connecting the upper wiring portion and the lower wiring portion to corresponding driving lines of the first plurality of driving lines in at least one of the first plurality of memory portions or the plurality of memory groups.

5. The semiconductor device of claim 4, wherein the penetrating plug comprises:
a conductive portion, and a side insulation layer on a side surface of the conductive portion.

6. The semiconductor device of claim 4, wherein the penetrating plug comprises a word plug configured to electrically connect the corresponding word lines in the first plurality of memory portions or the plurality of memory groups.

7. The semiconductor device of claim 4, wherein the penetrating plug comprises a bit plug configured to electrically connect the corresponding bit lines in the first plurality of memory portions or the plurality of memory groups.

8. The semiconductor device of claim 2, wherein the first wiring connection is the integrated connection, and the second wiring connection is the word-line connection or the bit-line connection.

9. The semiconductor device of claim 2, wherein the first wiring connection is the bit-line connection, and the second wiring connection is the word-line connection or the integrated connection.

10. The semiconductor device of claim 2, wherein the first wiring connection is the word-line connection, and the second wiring connection is the bit-line connection or the integrated connection.

11. The semiconductor device of claim 2, further comprising:
a word connection wiring that is connected to the corresponding word lines and is shared in the first plurality of memory portions;
a bit connection wiring that is connected to the corresponding bit lines in at least two memory portions among the first plurality of memory portions; and
an additional bit connection wiring that is connected to the corresponding bit lines in at least two other memory portions among the first plurality of memory portions.

12. The semiconductor device of claim 2, further comprising:
a bit connection wiring that is connected to the corresponding bit lines, the bit connection wiring being shared in the first plurality of memory portions,
a word connection wiring that is connected to the corresponding word lines in at least two memory portions among the first plurality of memory portions, and
an additional word connection wiring that is connected to the corresponding word lines in at least two other memory portions among the first plurality of memory portions.

13. The semiconductor device of claim 2, further comprising:
a word connection wiring that is connected to the corresponding word lines in at least two first memory portions among the first plurality of memory portions;
an additional word connection wiring that is connected to the corresponding word lines in at least two other first memory portions among the first plurality of memory portions;
a bit connection wiring that is connected to the corresponding bit lines in at least two second memory portions among the first plurality of memory portions; and
an additional bit connection wiring that is connected to the corresponding bit lines in at least two other second memory portions among the first plurality of memory portions.

14. The semiconductor device of claim 1, wherein a memory cell block is associated with a part of the plurality of memory groups to be associated with one or more memory portions.

15. The semiconductor device of claim 14, wherein the memory cell block is associated with each of the plurality of memory portions.

16. The semiconductor device of claim 1, wherein more than one memory portion of the plurality of memory portions in the plurality of memory groups are stacked on each other in a thickness direction, and
wherein the circuit region and the plurality of memory portions are bonded by hybrid bonding.

17. A semiconductor device, comprising:
a circuit region and a cell region stacked on the circuit region,
wherein the cell region comprises a plurality of memory sets,
wherein each of the plurality of memory sets comprises a plurality of memory groups,
wherein each of the plurality of memory groups comprises a plurality of memory portions, and
wherein a first plurality of memory portions in a first memory group from the plurality of memory groups are connected to through a first wiring connection,
wherein the first memory group among the plurality of memory groups is connected to a second memory group among the plurality of memory groups through a second wiring connection different from the first wiring connection in each of the memory set, and
wherein the plurality of memory sets are connected to each other through a third wiring connection different from the second wiring connection.

18. The semiconductor device of claim 17, wherein the third wiring connection is different from the first wiring connection.

19. The semiconductor device of claim 17, wherein the first plurality of memory portions comprises a first plurality of driving lines,
wherein the first plurality of driving lines comprise a first plurality of word lines and a first plurality of bit lines, wherein the first plurality of bit lines extend in a direction intersecting the first plurality of word lines,
wherein the first wiring connection is one of:
a word-line connection in which corresponding word lines of the first plurality of word lines are connected,
a bit-line connection in which corresponding bit lines of the first plurality of bit lines are connected, and
an integrated connection in which the corresponding word lines are connected and the corresponding bit lines are connected,
wherein the second wiring connection is another connection among the word-line connection, the bit-line connection, and the integrated connection, and
wherein the third wiring connection structure is another connection among the word-line connection, the bit-line connection, and the integrated connection.

20. An electronic system, comprising:
a main substrate;
a semiconductor device on the main substrate; and
a controller connected to the semiconductor device on the main substrate,
wherein the semiconductor device comprises a circuit region and a cell region stacked on the circuit region,
wherein the cell region comprises a plurality of memory groups,
wherein each of the plurality of memory groups comprises a plurality of memory portions,
wherein a first plurality of memory portions in a first memory group from the plurality of memory groups are connected to through a first wiring connection, and
wherein the first memory group among the plurality of memory groups is connected to a second memory group among the plurality of memory groups through a second wiring connection different from the first wiring connection.
